(19) United States
(12) Patent Application Publication
(10) Pub. No.: US 2009/0323300 A1
(43) Pub. Date: Dec. 31, 2009

(54) Conductor Foil with Adhesive Layer, Conductor-Clad Laminate, Printed Wiring Board and Multilayer Wiring Board

(76) Inventors: Daisuke Fujimoto, Ibaraki (JP); Yasuyuki Mizuno, Ibaraki (JP); Kazutoshi Danjobara, Ibaraki (JP); Katsuyuki Masuda, Ibaraki (JP); Hikari Murai, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/298,337

(22) PCT Filed: Apr. 24, 2007
(86) PCT No.: PCT/JP2007/058863

§ 371 Date: Aug. 4, 2009

(30) Foreign Application Priority Data
Apr. 25, 2006 (JP) 2006-120477
Oct. 24, 2006 (JP) 2006-288722
Mar. 29, 2007 (JP) 2007-088894
Mar. 29, 2007 (JP) 2007-089055

(51) Int. Cl. H05K 1/14; B32B 7/12; B32B 5/16; B32B 3/10; B32B 27/34; B32B 27/04; H05K 1/00

(52) U.S. Cl. 361/784; 428/355 R; 428/327; 428/336; 428/141; 428/473.5; 442/115; 361/748

(57) ABSTRACT

The invention provides an adhesive layer-attached conductive foil and a conductor-clad laminated sheet which allow transmission loss to be satisfactorily reduced especially in the high-frequency band, which exhibit excellent heat resistance, and which allow production of printed circuit boards that are adequately resistant to interlayer peeling. The adhesive layer-attached conductive foil of the invention is provided with a conductive foil and an adhesive layer formed on the conductive foil, wherein the adhesive layer is composed of a curable resin composition containing component (A): a polyfunctional epoxy resin, component (B): a polyfunctional phenol resin and component (C): a polyamideimide. The conductor-clad laminated sheet of the invention comprises an insulating layer, a conductive layer situated facing the insulating layer, and an adhesive layer sandwiched between the insulating layer and conductive layer, and the adhesive layer is composed of a cured resin composition containing components (A), (B) and (C).

### TECHNICAL FIELD

The present invention relates to an adhesive layer-attached conductive foil, a conductor-clad laminated sheet, a printed circuit board and a multilayer interconnection board.

### BACKGROUND ART

Mobile communication devices such as cellular phones and network-related electronic devices such as base station devices, servers and routers, or large computers and the like, must transmit and process large volumes of data with low loss and high speed. In order to meet this requirement, the printed circuit boards mounted in such devices are being designed to deal with electrical signals of increasingly high frequency. However, since it is the nature of electrical signals to be more prone to damping with higher frequency, there is a demand for even greater transmission loss in the printed circuit boards that utilize high-frequency electrical signals.

Conventional strategies for obtaining printed circuit boards with low transmission loss have included using fluorine-based resin-containing thermoplastic resin materials with low relative permittivity or a low dielectric loss tangent as base materials for printed circuit boards. Fluorine-based resins, however, generally have high melt viscosities and low flow properties, and since high-temperature, high-pressure conditions must be set for their press molding, their molding cannot always be conveniently accomplished. Materials for printed circuit boards used in communication devices such as those mentioned above have had drawbacks such as inadequate workability, dimensional stability and adhesion with metal platings.

It has therefore been attempted to use thermosetting resin compositions with low relative permittivity and dielectric loss tangent instead of thermoplastic resin materials. The following types of thermosetting resin compositions are known for use as starting materials for dielectric materials in the electronic devices mentioned above. Specifically, Patent documents 1-3 disclose resin compositions containing triallyl cyanurate or triallyl isocyanurate. Also, Patent documents 1, 2, 4 and 5 disclose resin compositions containing polybutadiene. Patent document 6 discloses a resin composition containing a thermosetting polyphenylene ether imparted with a radical crosslinking functional group such as allyl, with the aforementioned triallyl cyanurate or triallyl isocyanurate. Taken together, these patent documents teach that the aforementioned thermosetting resin compositions can exhibit low transmission loss because they have few polar groups after curing.

In a printed circuit board, it is desirable to achieve high adhesion between the insulating layer and the conductive layer formed thereover. Low adhesion between the insulating layer and conductive layer tends to result in the inconvenience of their peeling during use. A printed circuit board is usually formed by working the conductive foil of a conductor-clad laminated sheet which is obtained by laminating a conductive foil on an insulating layer, and in order to achieve excellent adhesion between the insulating layer and conductive layer it is important to ensure high adhesion between the insulating layer and conductive foil of the conductor-clad laminated sheet.

Metal-clad laminated sheets, obtained by laminating and molding a prepreg sheet with a copper foil coated with polybutadiene that has been modified with epoxy, maleic acid, carboxylic acid or the like, are known for this purpose (see Patent documents 7 and 8). There are also known printed circuit boards comprising an epoxy compound- or polyamideimide compound-containing layer between the insulating layer and conductive layer (see Patent documents 9 and 10). A method of setting an adhesion-promoting elastomer layer composed of an ethylene-propylene elastomer or the like between the copper foil and insulating layer has also been proposed (see Patent document 11).

[Patent document 1] Japanese Examined Patent Publication HEI No. 6-69746
[Patent document 2] Japanese Examined Patent Publication HEI No. 7-47689
[Patent document 3] Japanese Unexamined Patent Publication No. 2002-265777
[Patent document 4] Japanese Examined Patent Publication SHO No. 58-21925
[Patent document 5] Japanese Unexamined Patent Publication HEI No. 10-117052
[Patent document 6] Japanese Examined Patent Publication HEI No. 6-92533
[Patent document 7] Japanese Unexamined Patent Publication SHO No. 54-74883
[Patent document 8] Japanese Unexamined Patent Publication SHO No. 55-86744
[Patent document 9] Japanese Unexamined Patent Publication No. 2005-167172
[Patent document 10] Japanese Unexamined Patent Publication No. 2005-167173
[Patent document 11] Japanese Unexamined Patent Publication No. 2005-502192

### DISCLOSURE OF THE INVENTION

### Problems to be Solved by the Invention

Recent years have seen increasing demand for electronic devices such as mentioned above that can handle even higher frequency electrical signals. However, it is becoming difficult to adequately handle such higher frequencies simply by using the low permittivity and low dielectric loss tangent resins such as described in Patent documents 1-6, for example, as dielectric materials to obtain low transmission loss of electrical signals in the insulating layer (dielectric layer). Specifically, the electrical signal transmission loss is due to both loss attributed to the insulating layer (dielectric loss) and loss attributed to the conductive layer (conductor loss), and with the increasingly higher frequencies used in recent years, it has become necessary to not only reduce dielectric loss by improving the dielectric material as in the prior art, but also to reduce conductor loss.

In particular, most printed circuit boards currently implemented (multilayer interconnection boards) place a limit of no greater than 200 μm on the thickness of the insulating layer situated between the signal layer and the ground layer as the conductive layers. When a resin with a reasonably low permittivity or dielectric loss tangent is used as the material for the insulating layer, it is the conductor loss rather than the dielectric loss that governs the transmission loss of the circuit board as a whole.

As a method for achieving reduced conductor loss there may be mentioned one employing a conductive foil with low surface irregularities on the surface of the side of the conductive layer that bonds with the insulating layer (the roughened side, which will hereinafter referred to as the “M-surface”). Specifically, there may be used a conductor-clad laminated sheet comprising a conductive foil with an M-surface roughness (ten-point height of irregularities; Rz) of no greater than 4 μm and especially 2 μm (such a conductive foil will hereinafter be referred to as a “low-roughened foil”).

Based on this knowledge, the present inventors conducted detail investigation by fabricating printed circuit boards using resins with low permittivity and a low dielectric loss tangent, cured by polymerization of vinyl groups or allyl groups as described in Patent documents 1-6, with the low-roughened foil mentioned above. As a result it was confirmed that, because of the low polarity of the insulating layer and the low anchor effect due to irregularities on the M-surface of the conductive foil in such printed circuit boards, the adhesive force (bonding force) between the insulating layer and conductive layer is weak and peeling readily occurs between the layers. Such peeling tends to be particularly notable when the printed circuit board is heated (especially when heated after moisture absorption). It has been found, therefore, that when such a resin is used as a dielectric material and a low-roughened foil is employed to reduce conductor loss, it becomes difficult to ensure adequate adhesion between the insulating layer and conductive layer.

Moreover, when means such as described in Patent documents 7 and 8 is applied to fabricate a printed circuit board by attaching an insulating layer to a low-roughened copper foil with an M-surface Rz of no greater than 2 μm via modified polybutadiene, the peel strength of the copper foil is not sufficiently high, and reduced heat resistance (particularly heat resistance during moisture absorption) has been observed.

When means such as described in Patent documents 9 and 10 is applied to fabricate a printed circuit board by using an adhesive layer-attached copper foil obtained by pre-forming a polyamideimide resin to a thickness of 0.1-5 μm on the surface of a low-roughened copper foil with an M-surface Rz of no greater than 2 μm, it has been confirmed that high copper foil peel strength is obtained. However, it has also been shown that the low anchor effect, attributed to irregularities in the M-surface of the conductive foil, causes weakening of the adhesive force (bonding force) between the polyamideimide resin and insulating layer, and causes peeling to easily occur between them during heating, for example (especially during heating after moisture absorption).

Methods such as described in Patent document 11 have also been applied to fabricate a printed circuit board using an adhesive layer-attached copper foil, obtained by pre-forming an adhesion-promoting elastomer layer containing an elastomer such as a styrene-butadiene elastomer to a thickness of 3-15 μm on the surface of a low-roughened copper foil with an M-surface Rz of no greater than 4 μm. This method results in high copper foil peel strength, but the anchor effect of the irregularities on the M-surface of the conductive foil tends to be inconveniently reduced. This has been found to weaken the adhesive force (bonding force) with the insulating layer via the adhesion-promoting elastomer layer, thus tending to cause peeling between the layers when they are heated.

The present invention has been accomplished in light of these circumstances, and one of its objects is to provide an adhesive layer-attached conductive foil that can satisfactorily reduce transmission loss particularly in the high-frequency band, and that can produce printed circuit boards with excellent heat resistance and sufficient resistance to interlayer peeling. It is another object of the invention to provide a conductor-clad laminated sheet, a printed circuit board and a multilayer interconnection board obtained using the adhesive layer-attached conductive foil.

### Means for Solving the Problems

In order to achieve the objects stated above, the adhesive layer-attached conductive foil of the invention is an adhesive layer-attached conductive foil provided with a conductive foil and an adhesive layer formed on the conductive foil, characterized in that the adhesive layer is composed of a curable resin composition containing component (A): a polyfunctional epoxy resin, component (B): a polyfunctional phenol resin and component (C): a polyamideimide.

The adhesive layer of the adhesive layer-attached conductive foil of the invention is composed of a curable resin composition containing the aforementioned components (A) to (C). The curable resin composition, when cured, contains a cured polyfunctional epoxy resin and cured polyfunctional phenol resin, as well as a polyamideimide, and it therefore exhibits highly superior adhesion for low-roughened foils or for insulating layers with low permittivity. Also, the curable resin composition when cured exhibits excellent heat resistance since it contains the aforementioned three components.

Consequently, when the adhesive layer-attached conductive foil is used to produce a conductor-clad laminated sheet or printed circuit board such as described hereunder, the insulating layer and conductive layer bond together firmly via the cured adhesive layer of the adhesive layer-attached conductive foil, thus allowing peeling between them to be large prevented. In addition, significantly low transmission loss can be achieved due to the low permittivity and low dielectric loss tangent of the adhesive cured layer. Furthermore, the excellent heat resistance of the adhesive cured layer results in excellent heat resistance of the board as whole. For distinction in the explanation which follows, the cured adhesive layer composed of the curable resin composition will be referred to as “adhesive cured layer”, while the insulating layer serving as the base material of the conductor-clad laminated sheet or printed circuit board will be referred to as “insulating layer” or “insulating resin layer”.

Component (C) in the adhesive layer-attached conductive foil of the invention is preferably a polyamideimide with a weight-average molecular weight of between 50,000 and 300,000.

If component (C) (polyamideimide) has a weight-average molecular weight of between 50,000 and 300,000, further improvement in heat resistance will be achieved, and more satisfactory adhesive strength will be realized by the adhesive cured layer for the conductive foil or insulating layer. While the reason for this is not fully understood, it is believed to be as follows. The adhesive layer in the adhesive layer-attached conductive foil of the invention forms sea-island structures after curing, due the presence of components (A), (B) and (C). Specifically, sea layers composed of regions of component (C) and island layers composed of regions of components (A) and (B) are formed. In the adhesive cured layer, this sea-island structure is presumably responsible for both the excellent adhesion attributed to component (C) and high heat resistance attributed to components (A) and (B). A particularly well-defined sea-island structure is formed when the weight-average molecular weight of component (C) is at least 50,000, while component (C) will maintain a good flow property in the adhesive layer if it is less than 300,000, thus resulting in satisfactory bonding with the conductive foil or insulating layer. Therefore, using an adhesive layer-attached conductive foil according to the invention can be expected to result in satisfactory heat resistance of the adhesive cured layer and adhesion with the conductive foil.

Component (A) and component (B) in the curable resin composition composing the adhesive layer of the adhesive layer-attached conductive foil of the invention are preferably such that their mixture has a post-curing glass transition temperature of above 150° C. If this condition is satisfied, the heat resistance of the adhesive cured layer will be even more satisfactory and printed circuit boards obtained using the adhesive layer-attached conductive foil of the invention will also have excellent heat resistance in a practical temperature range. The glass transition temperature (Tg) may be measured by differential scanning calorimetry (DSC) according to JIS-K7121-1987.

The polyfunctional epoxy resin as component (A) in the curable resin composition is preferably at least one polyfunctional epoxy resin selected from the group consisting of phenol-novolac-type epoxy resins, cresol-novolac-type epoxy resins, brominated phenol-novolac-type epoxy resins, bisphenol A-novolac-type epoxy resins, biphenyl-type epoxy resins, naphthalene backbone-containing epoxy resins, aralkylene backbone-containing epoxy resins, biphenyl-aralkylene backbone-containing epoxy resins, phenolsalicylaldehyde-novolac-type epoxy resins, lower alkyl group-substituted phenolsalicylaldehyde-novolac-type epoxy resins, dicyclopentadiene backbone-containing epoxy resins, polyfunctional glycidylamine-type epoxy resins and polyfunctional alicyclic epoxy resins.

The polyfunctional phenol resin as component (B) preferably contains at least one polyfunctional phenol resin selected from the group consisting of aralkyl-type phenol resins, dicyclopentadiene-type phenol resins, salicylaldehyde-type phenol resins, copolymer resins of benzaldehyde-type phenol resins and aralkyl-type phenol resins, and novolac-type phenol resins.

These polyfunctional epoxy resins and polyfunctional phenol resins may be combined with other components according to the invention to impart excellent adhesion and heat resistance to the adhesive cured layer.

The polyamideimide as component (C) preferably contains a structural unit comprising a saturated hydrocarbon. If a polyamideimide containing a structural unit comprising a saturated hydrocarbon is used, the conductive foil or insulating layer adhesion provided by the adhesive cured layer will be satisfactory, and more particularly, satisfactory adhesion will be maintained even with moisture absorption. As a result, printed circuit boards obtained using the adhesive layer-attached conductive foil of the invention will be highly resistant to interlayer peeling even after moisture absorption. The mixing proportion of component (C) in the curable resin composition composing the adhesive layer is preferably 0.5-500 parts by weight and more preferably 10-400 parts by weight with respect to 100 parts by weight as the total of component (A) and component (B). If the mixing proportion of component (C) is within this range, satisfactory adhesion will be obtained and the toughness, heat resistance and chemical resistance of the adhesive cured layer will tend to be notably improved.

The curable resin composition preferably further contains crosslinked rubber particles and/or a polyvinylacetal resin as component (D). Including such components will further improve the adhesion onto conductive foils and the like, which is provided by the adhesive cured layer.

From the viewpoint of obtaining these properties even more satisfactorily, component (D) is preferably at least one type of crosslinked rubber particles selected from the group consisting of acrylonitrile-butadiene rubber particles, carboxylic acid-modified acrylonitrile-butadiene rubber particles, carboxylic acid-modified acrylonitrile-butadiene rubber particles and butadiene rubber-acrylic resin core-shell particles.

The adhesive layer in the adhesive layer-attached conductive foil of the invention is preferably obtained by coating the surface of the conductive foil with a resin varnish containing the curable resin composition and a solvent to form a resin varnish layer, and then removing the solvent from the resin varnish layer. The adhesive layer formed in this manner is a homogeneous layer in terms of thickness and properties, and it readily exhibits excellent adhesion with conductive foils and the like after curing.

The adhesive layer of the adhesive layer-attached conductive foil preferably has a thickness of 0.1-10 μm and more preferably a thickness of 0.1-5 μm. An adhesive layer with this range of thickness will provide sufficient adhesion with conductive foils while also satisfactorily reducing dielectric loss.

Also, the ten-point height of irregularities (Rz) on the surface of the adhesive layer side of the conductive foil is preferably no greater than 4 μm and more preferably no greater than 2 μm. Such a small M-surface roughness reduces the conductor loss from the conductive layer formed on the conductive foil, so that a printed circuit board obtained using the adhesive layer-attached conductive foil of the invention exhibits satisfactory reduction not only in dielectric loss but also in conductor loss. The ten-point height of irregularities (Rz) is the ten-point height of irregularities as defined by JIS B0601-1994.

A conductor-clad laminated sheet according to the invention is characterized in that it is obtained by laminating the aforementioned adhesive layer-attached conductive foil of the invention onto at least one side of an insulating resin film containing a resin with an insulating property, so that the adhesive layer of the adhesive layer-attached conductive foil contacts therewith, to obtain a laminated body, and then heating and pressing the laminated body.

The conductor-clad laminated sheet obtained in this manner comprises an insulating layer and a conductive layer laminated on the insulating layer via an adhesive cured layer, where the adhesive cured layer and conductive layer are formed from an adhesive layer-attached conductive foil of the invention, the adhesive cured layer consisting of the cured adhesive layer of the adhesive layer-attached conductive foil and the conductive layer consisting of the conductive foil of the adhesive layer-attached conductive foil.

Specifically, the conductor-clad laminated sheet of the invention may comprise an insulating layer, a conductive layer situated facing the insulating layer and an adhesive cured layer sandwiched between the insulating layer and conductive layer, wherein the adhesive cured layer consists of a cured resin composition comprising component (A): a polyfunctional epoxy resin, component (B): a polyfunctional phenol resin and component (C): a polyamide resin.

Since the insulating layer (insulating resin film) and conductive layer (conductive foil) in the conductor-clad laminated sheet of the invention are bonded via a layer (adhesive cured layer) composed of a cured resin composition comprising components (A), (B) and (C) mentioned above, the adhesion between the conductive layer and insulating layer is excellent. It is therefore resistant to interlayer peeling even when a low-roughened foil is used as the conductive layer. The adhesive cured layer also has low permittivity and a low dielectric loss tangent. A printed circuit board obtained from such a conductor-clad laminated sheet is therefore highly resistant to interlayer peeling.

The insulating layer in the conductor-clad laminated sheet of the invention is constructed using an insulating resin and a base material situated in the insulating resin, and the base material preferably comprises a woven fabric or nonwoven fabric of fibers composed of one or more materials selected from the group consisting of glass, paper and organic high molecular compounds. This will more reliably reduce the transmission loss and help to achieve improved heat resistance and inhibit interlayer peeling.

The insulating layer preferably contains a resin with an ethylenic unsaturated bond as the insulating resin. More specifically, the insulating resin preferably contains at least one resin selected from the group consisting of polybutadiene, polytriallyl cyanurate, polytriallyl isocyanurate, unsaturated group-containing polyphenylene ethers and maleimide compounds. These resins have low permittivity and low dielectric loss tangents, and can therefore drastically reduce the dielectric loss.

Alternatively, the insulating resin also preferably contains at least one resin selected from the group consisting of polyphenylene ethers and thermoplastic elastomers. These resins also have low permittivity and low dielectric loss tangents, and can likewise drastically reduce the dielectric loss.

The insulating layer preferably has a relative permittivity of no greater than 4.0 at 1 GHz. An insulating layer satisfying this condition will help to significantly reduce the dielectric loss. A printed circuit board obtained from such a conductor-clad laminated sheet will therefore have very low transmission loss.

The printed circuit board of the invention can be used ordinarily as a printed circuit board, by working the conductive foil in the conductor-clad laminated sheet of the invention into a prescribed circuit pattern. The printed circuit board is highly resistant to peeling between the conductive foil circuit pattern and insulating resin layer even when a low-roughened foil is used, while the excellent heat resistance of the adhesive cured layer provides excellent heat resistance for the board as a whole.

The invention can further provide a multilayer interconnection board which is resistant to interlayer peeling and which has high heat resistance, since it comprises a printed circuit board according to the invention. Specifically, the multilayer interconnection board of the invention is a multilayer interconnection board comprising a core board having at least one printed circuit board layer, and an outer circuit board having at least one printed circuit board layer and situated on at least one side of the core board, characterized in that at least one printed circuit board layer of the core board is a printed circuit board according to the invention.

Printed circuit boards that handle high frequencies, applied in electronic devices such as mentioned above, must exhibit low transmission loss and satisfactory impedance control. In order to realize such properties, it is important to improve precision for formation to a satisfactory pattern width on the conductive layer during fabrication of the printed circuit board. Using a conductive foil with low surface roughness, such as a low-profile foil, is advantageous for improving precision of conductor pattern formation and realizing even finer patterns.

In this context, the adhesive layer-attached conductive foil of the invention exhibits adequate adhesion between the insulating layer and conductive foil even when a low-roughened foil is used and when an insulating resin material with low permittivity and a low dielectric loss tangent is used for the insulating layer. Therefore, with a printed circuit board employing the adhesive layer-attached conductive foil of the invention it is possible to realize not only low transmission loss but also satisfactory impedance control.

At the current time it is not fully understood why the adhesive layer-attached conductive foil of the invention exhibits such excellent adhesion, but the present inventors have conjectured as follows. When a low-roughened foil, for example, is used as the conductive foil, the adhesion of the low-roughened foil for the insulating layer is reduced and interlayer peeling tends to occur, even with multilayering of multiple conductor-clad laminated sheets comprising the low-roughened foil. Specifically, when the conductive foil of a conductor-clad laminated sheet obtained by laminating a low-roughened foil with an M-surface Rz of 4 μm or less on both sides of an insulating resin layer is removed and a prepreg and conductive foil are stacked thereover in that order to fabricate a multilayer laminated sheet and then a printed circuit board, the roughness transferred to the inner insulating resin layer is also low due to the low-roughened foil.

In a multilayer laminated sheet obtained in this manner, the anchor effect between the insulating resin layer and prepreg in the conductor-clad laminated sheet is less than when using an ordinary copper foil (Rz=≧6 μm), and this reduces the adhesive force (bonding power) between the insulating resin layer and prepreg. As a result, the conductive foil situated on the surface of the prepreg is prone to peeling from the insulating resin layer. This tendency is particularly notable with heating (especially heating after moisture absorption).

In such cases, using a conductor-clad laminated sheet obtained by laminating an adhesive layer-attached conductive foil on the surface of an insulating resin layer can minimize such adhesive force reduction. Specifically, when the conductor-clad laminated sheet is used to form a multilayer laminated sheet, the adhesive layer of the adhesive layer-attached conductive foil will lie between the insulating resin layer and the prepreg, thereby providing some improvement in the adhesion between the layers.

In this case, however, the heat resistance is insufficient for a printed circuit board if a resin material consisting entirely of polyamideimide or a combination of a polyamideimide and an epoxy resin is used for the adhesive layer. This is thought to be due to the fact that such resin materials, while exhibiting good adhesion, are susceptible to hydrogen bonding with water and thus have less than ideal heat resistance after moisture absorption.

In contrast, components (A) and (B) in the adhesive layer of an adhesive layer-attached conductive foil according to the invention exhibit excellent post-curing heat resistance (especially heat resistance after moisture absorption). Consequently, multilayer interconnection boards and printed circuit boards obtained using the adhesive layer-attached conductive foil exhibit excellent heat resistance as a whole. Furthermore, since components (A) and (B) have excellent adhesion for insulating resin layers and conductive foils, the adhesive cured layer can maintain sufficient adhesion even with reduced addition of polyamideimide as component (C). In addition, since polyamideimides generally tend to lower the heat resistance (especially heat resistance after moisture absorption) of adhesive cured layers, the adhesive layer-attached conductive foil of the invention can be designed to have even greater heat resistance while limiting the amount of added polyamideimide to the minimum necessary.

Because of these factors, a printed circuit board or multilayer interconnection board obtained using the adhesive layer-attached conductive foil or conductor-clad laminated sheet of the invention has a specified adhesive cured layer between the conductive layer (circuit pattern) and insulating layer, and therefore the adhesion between the conductive layer and insulating layer is satisfactory and the heat resistance is also excellent, even when it comprises a conductive layer with a smooth adhesive side and an insulating layer with low dielectric loss.

### EFFECT OF THE INVENTION

According to the invention it is possible to provide an adhesive layer-attached conductive foil and a conductor-clad laminated sheet which allow transmission loss to be satisfactorily reduced especially in the high-frequency band, and which allow production of printed circuit boards that are adequately resistant to interlayer peeling. It is also possible to provide printed circuit boards and multilayer interconnection boards obtained using the adhesive layer-attached conductive foil or conductor-clad laminated sheet.

### BRIEF DESCRIPTION OF THE DRAWINGS

FIG. 1 is a partial perspective view of an adhesive layer-attached conductive foil according to a preferred embodiment.

FIG. 2 shows the partial cross-sectional construction of a conductor-clad laminated sheet according to a first example.

FIG. 3 shows the partial cross-sectional construction of a conductor-clad laminated sheet according to a second example.

FIG. 4 shows the partial cross-sectional construction of a printed circuit board according to a first example.

FIG. 5 shows the partial cross-sectional construction of a printed circuit board according to a second example.

FIG. 6 shows the partial cross-sectional construction of a multilayer interconnection board according to a first example.

FIG. 7 shows the partial cross-sectional construction of a multilayer interconnection board according to a second example.

### EXPLANATION OF SYMBOLS

10: Conductive foil, 11: circuit pattern, 12: M-surface, 20: adhesive layer, 22: insulating layer, 24: adhesive cured layer, 26: conductive layer, 30: adhesive cured layer, 32: insulating layer, 34: adhesive cured layer, 36: circuit pattern, 40: insulating resin layer, 50: insulating layer, 60: plated coating, 62: insulating layer, 64: adhesive cured layer, 66: inner circuit pattern, 68: interlayer insulating layer, 70: through-hole, 72: outer circuit pattern, 74: via hole, 76: through-hole, 80: core board, 90: adhesive cured layer, 92: insulating resin layer, 94: plated coating, 96: through-hole, 100: adhesive layer-attached conductive foil, 110: outer circuit pattern, 200: conductor-clad laminated sheet, 300: conductor-clad laminated sheet, 400: printed circuit board, 500: printed circuit board, 510: core board, 600: multilayer interconnection board, 700: multilayer interconnection board.

### BEST MODE FOR CARRYING OUT THE INVENTION

Preferred embodiments of the invention will now be explained in detail, with reference to the accompanying drawings as necessary. Identical elements in the drawings will be referred to by like reference numerals and will be explained only once. The vertical and horizontal positional relationships are based on the positional relationships in the drawings, unless otherwise specified. Also, the dimensional proportions depicted in the drawings are not necessarily limitative.

### [Adhesive Layer-Attached Conductive Foil]

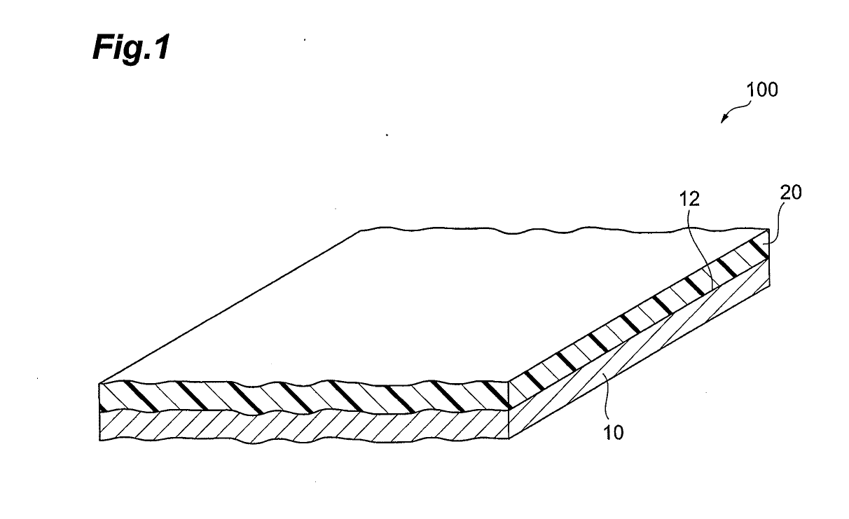

An adhesive layer-attached conductive foil according to a preferred embodiment will be explained first. FIG. 1 is a partial perspective view of an adhesive layer-attached conductive foil according to a preferred embodiment. The adhesive layer-attached conductive foil 100 shown in FIG. 1 has a construction provided with a conductive foil 10 and an adhesive layer 20 formed in contact with the roughened surface (M-surface) 12 of the conductive foil 10.

(Conductive Foil)

The conductive foil 10 is not particularly limited so long as it is suitable as a conductive layer for a conventional printed circuit board or the like. For example, a metal foil such as a copper foil, nickel foil or aluminum foil may be used as the conductive foil. Electric field copper foils and rolled copper foils are preferred. The conductive foil 10 is preferably subjected to barrier layer-forming treatment with nickel, tin, zinc, chromium, molybdenum, cobalt or the like, from the viewpoint of improving the rust resistance, chemical resistance and heat resistance. From the viewpoint of improving the adhesion with insulating layers, it is preferably subjected to surface treatment, such as surface roughening treatment or treatment with a silane coupling agent.

Among such surface treatments, surface roughening treatment is preferably carried out to a surface roughness (Rz) of preferably no greater than 4 μm and more preferably no greater than 2 μm for the M-surface 12. This will tend to further enhance the high-frequency transmission characteristics. There are no particular restrictions on the silane coupling agent used for silane coupling agent treatment, and there may be mentioned epoxysilanes, aminosilanes, cationic silanes, vinylsilanes, acryloxysilanes, methacroyloxysilanes, ureidosilanes, mercaptosilanes, sulfidosilanes and isocyanatosilanes.

The conductive foil 10 may have a monolayer structure composed of one type of metal material or a monolayer structure composed of multiple metal materials, or it may instead have a laminated structure comprising a plurality of laminated metal layers of different materials. The thickness of the conductive foil 10 is not particularly restricted. Such conductive foils 10 that are suitable for use are commercially available as, for example, the copper foils F1-WS (trade name of Furukawa Circuit Foil Co., Ltd., Rz=1.9 μm), F2-WS (trade name of Furukawa Circuit Foil Co., Ltd., Rz=2.0 μm), F0-WS (trade name of Furukawa Circuit Foil Co., Ltd., Rz=1.0 μm), HLP (trade name of Nippon Mining & Metals Co., Ltd., Rz=0.7 μm) and T9-SV (trade name of Fukuda Metal Foil & Powder Co., Ltd., Rz=1.8 μm).

(Adhesive Layer)

The adhesive layer 20 of the adhesive layer-attached conductive foil 100 is a layer comprising a curable resin composition which contains component (A): a polyfunctional epoxy resin, component (B): a polyfunctional phenol resin and component (C): a polyamideimide. The thickness of the adhesive layer 20 is preferably 0.1-10 μm and more preferably 0.1-5 μm. If the thickness is less than 0.1 μm it will tend to be difficult to obtain sufficient peel strength for the conductive foil (conductive layer) in the conductor-clad laminated sheet described hereunder. If it exceeds 10 μm, on the other hand, the high-frequency transmission characteristics of the conductor-clad laminated sheet will tend to be reduced. Each of the components of the curable resin composition composing the adhesive layer 20 will now be explained.

Component (A) will be explained first.

The polyfunctional epoxy resin as component (A) is a compound having multiple epoxy groups in a single molecule, and a plurality of molecules can become bonded by reaction between the epoxy groups. As examples for component (A) there may be mentioned phenol-novolac-type epoxy resins, cresol-novolac-type epoxy resins, brominated phenol-novolac-type epoxy resins, bisphenol A-novolac-type epoxy resins, biphenyl-type epoxy resins, naphthalene backbone-containing epoxy resins, aralkylene backbone-containing epoxy resins, biphenyl-aralkylene backbone-containing epoxy resins, phenolsalicylaldehyde-novolac-type epoxy resins, lower alkyl group-substituted phenolsalicylaldehyde-novolac-type epoxy resins, dicyclopentadiene backbone-containing epoxy resins, polyfunctional glycidylamine-type epoxy resins and polyfunctional alicyclic epoxy resins. Any one of these may be added alone or a combination of two or more thereof may be added in combination, as component (A).

Preferred among these for component (A) are cresol-novolac-type epoxy resins, biphenyl-type epoxy resins and phenol-novolac-type epoxy resins. Including such polyfunctional epoxy resins as component (A) will help provide more excellent adhesion and electrical characteristics by the cured adhesive layer 20 (adhesive cured layer).

Component (B) will be explained next.

The polyfunctional phenol compound as component (B) is a compound having multiple phenolic hydroxyl groups in a single molecule, and it functions as the curing agent for the polyfunctional epoxy resin used as component (A). As resins for component (B) there may be mentioned aralkyl-type phenol resins, dicyclopentadiene-type phenol resins, salicylaldehyde-type phenol resins, copolymer resins of benzaldehyde-type phenol resin and aralkyl-type phenol resin, and novolac-type phenol resins. Any one of these compounds may be added alone or a combination of two or more thereof may be added in combination, as component (B).

Component (A) and component (B) are preferably selected so that their mixture, when cured, has a glass transition temperature of above 150° C. If the cured mixture of component (A) and component (B) satisfies this condition, the post-moisture absorption heat resistance of the adhesive cured layer obtained after curing will tend to be improved. As a result, printed circuit boards obtained using the adhesive layer-attached conductive foil 100 will also exhibit excellent heat resistance in a practical temperature range.

Component (C) will be explained next.

The polyamideimide as component (C) is a polymer with a repeating unit containing an amide structure and an imide structure. Component (C) for this embodiment preferably has a weight-average molecular weight (Mw) of between 20,000 and 300,000, more preferably a Mw of between 50,000 and 300,000 and even more preferably a Mw of between 50,000 and 250,000. The value used for Mw may be the value measured by gel permeation chromatography and calculated using a calibration curve prepared using standard polystyrene.

If the molecular weight of component (C) is less than 20,000, adhesion between the adhesive cured layer and conductive foil (conductive layer) will tend to be inconveniently reduced in the adhesive layer-attached conductive foil obtained using the curable resin composition containing component (C) and in the printed circuit board obtained using the adhesive layer-attached conductive foil. This tendency becomes even more notable when the thickness of the conductive foil is reduced. On the other hand, a molecular weight of greater than 300,000 will tend to impair the flow property of the polyamideimide, thus reducing adhesion between the adhesive cured layer and conductive foil (conductive layer). This tendency likewise becomes more notable when the thickness of the conductive foil is reduced.

Component (C) preferably contains a structural unit comprising a saturated hydrocarbon in the molecule. If component (C) contains a saturated hydrocarbon, the adhesion provided by the adhesive cured layer for conductive foils and the like will be satisfactory. Also, because the humidity resistance of component (C) is improved, the adhesion provided by the adhesive cured layer after moisture absorption will also be satisfactorily maintained. As a result, a printed circuit board obtained using the adhesive layer-attached conductive foil 100 of this embodiment will exhibit enhanced moisture and heat resistance. Component (C) most preferably contains on its main chain a structural unit comprising a saturated hydrocarbon.

The structural unit comprising a saturated hydrocarbon is most preferably a saturated alicyclic hydrocarbon group. A saturated alicyclic hydrocarbon group will result in particularly satisfactory adhesion by the adhesive cured layer during moisture absorption, and the adhesive cured layer will have a high Tg, thus further improving the heat resistance of the printed circuit board. This effect will tend to be obtained in a more stable manner when the Mw of component (C) is at least 20,000 and especially at least 50,000.

Component (C) more preferably contains a siloxane structure on the main chain. A siloxane structure is a structural unit resulting from repeated alternate bonding of silicon atoms and oxygen atoms with prescribed substituents. If component (C) contains a siloxane structure on the main chain, the properties such as elastic modulus and flexibility of the adhesive cured layer obtained by curing the adhesive layer 20 will be improved and the durability of printed circuit boards and the like obtained therefrom will be increased, while the drying efficiency of the curable resin composition will also be satisfactory, thus facilitating formation of the adhesive layer 20.

As examples of polyamideimides for component (C) there may be mentioned polyamideimides synthesized by an isocyanate method, by reaction between trimellitic anhydride and aromatic diisocyanates. As specific examples of isocyanate methods there may be mentioned methods of reacting an aromatic tricarboxylic anhydride with an ether bond-containing diamine compound in an excess of the diamine compound, and then reacting the product with a diisocyanate (for example, the method described in Japanese Patent Publication No. 2897186), and methods of reacting an aromatic diamine compound with trimellitic anhydride (for example, the method described in Japanese Unexamined Patent Publication HEI No. 04-182466).

Component (C) which contains a siloxane structure on the main chain can also be synthesized by an isocyanate method. As examples of specific synthetic methods there may be mentioned methods involving polycondensation of an aromatic tricarboxylic acid anhydride, an aromatic diisocyanate and a siloxanediamine compound (for example, the method described in Japanese Unexamined Patent Publication HEI No. 05-009254), methods involving polycondensation of an aromatic dicarboxylic acid or aromatic tricarboxylic acid with a siloxanediamine compound (for example, the method described in Japanese Unexamined Patent Publication HEI No. 06-116517), and methods involving reacting an aromatic diisocyanate with a mixture containing a diimidedicarboxylic acid obtained by reacting trimellitic anhydride with a mixture containing siloxanediamine and a diamine compound with at least three aromatic rings (for example, the method described in Japanese Unexamined Patent Publication HEI No. 06-116517). The curable resin composition of this embodiment which is used to form the adhesive layer 20 exhibits sufficiently high conductive foil peel strength even when using a component (C) that is synthesized by these publicly known methods.

A detailed explanation will now be provided regarding a process for production of a polyamideimide with a saturated hydrocarbon-containing structural unit (particularly a saturated alicyclic hydrocarbon group) on the main chain, as a polymer suitable for use as component (C).

Such a polyamideimide can be obtained by, for example, converting an imide group-containing dicarboxylic acid obtained by reacting trimellitic anhydride with a diamine compound containing a saturated hydrocarbon group, into an acid halide, optionally using a condensation agent, and reacting it with a diamine compound. Alternatively, it may be obtained by reacting a diisocyanate with an imide group-containing dicarboxylic acid obtained by reacting trimellitic anhydride with a saturated hydrocarbon group-containing diamine compound. The polyamideimide with a saturated alicyclic hydrocarbon group may be obtained using as the starting material for such methods a diamine compound with a saturated alicyclic hydrocarbon group as the saturated hydrocarbon group.

As diamine compounds with saturated hydrocarbon groups there may be mentioned, specifically, compounds represented by the following general formula (1a) or (1b).

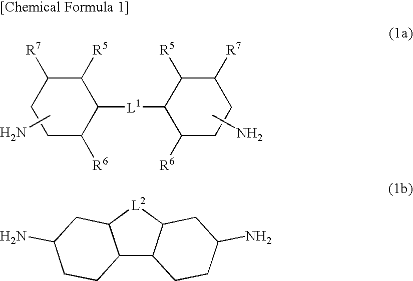

In formulas (1a) and (1b), L¹ represents an optionally halogen-substituted C1-3 divalent aliphatic hydrocarbon group, a sulfonyl, oxy or carbonyl group, a single bond or a divalent group represented by the following formula (2a) or (2b), L² represents an optionally halogen-substituted C1-3 divalent aliphatic hydrocarbon group or a sulfonyl, oxy or carbonyl group, and R⁵, R⁶ and R⁷ each independently represent hydrogen, hydroxyl, methoxy or an optionally halogen-substituted methyl group.

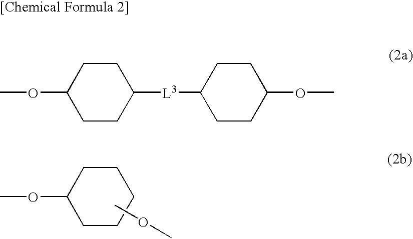

L³ in formula (2a) represents an optionally halogen-substituted C1-3 divalent aliphatic hydrocarbon group, a sulfonyl, oxy or carbonyl group, or a single bond.

The following compounds may be mentioned as specific examples of diamine compounds with saturated hydrocarbon groups such as represented by formula (1a) or (1b) above. Specific examples are 2,2-bis[4-(4-aminocyclohexyloxy)cyclohexyl]propane, bis[4-(3-aminocyclohexyloxy)cyclohexyl]sulfone, bis[4-(4-aminocyclohexyloxy)cyclohexyl]sulfone, 2,2-bis[4-(4-aminocyclohexyloxy)cyclohexyl]hexafluoropropane, bis[4-(4-aminocyclohexyloxy)cyclohexyl]methane, 4,4′-bis(4-aminocyclohexyloxy)dicyclohexyl, bis[4-(4-aminocyclohexyloxy)cyclohexyl]ether, bis[4-(4-aminocyclohexyloxy)cyclohexyl]ketone, 1,3-bis(4-aminocyclohexyloxy)benzene, 1,4-bis(4-aminocyclohexyloxy)benzene, 2,2′-dimethylbicyclohexyl-4,4′-diamine, 2,2′-bis(trifluoromethyl)dicyclohexyl-4,4′-diamine, 2,6,2′,6′-tetramethyl-4,4′-diamine, 5,5′-dimethyl-2,2′-sulfonyldicyclohexyl-4,4′-diamine, 3,3′-dihydroxydicyclohexyl-4,4′-diamine, (4,4′-diamino)dicyclohexyl ether, (4,4′-diamino)dicyclohexylsulfone, (4,4′-diaminocyclohexyl)ketone, (3,3′-diamino)benzophenone, (4,4′-diamino)dicyclohexylmethane, (4,4′-diamino)dicyclohexyl ether, (3,3′-diamino)dicyclohexyl ether, (4,4′-diamino)dicyclohexylmethane, (3,3′-diamino)dicyclohexyl ether and 2,2-bis(4-aminocyclohexyl)propane. Any one of these diamine compounds may be used alone, or two or more thereof may be used in combination. Other diamine compounds such as diamine compounds without saturated hydrocarbon groups may also be used for production of the polyamideimide of this embodiment, as described hereunder.

The diamine compound with a saturated hydrocarbon group can be easily obtained using, for example, an aromatic diamine compound with an aromatic ring having a structure corresponding to the saturated hydrocarbon group, and subjecting the aromatic ring to hydrogen reduction. As examples of such aromatic diamine compounds there may be mentioned 2,2-bis[4-(4-aminophenoxy)phenyl]propane (hereinafter abbreviated as “BAPP”), bis[4-(3-aminophenoxy)phenyl]sulfone, bis[4-(4-aminophenoxy)phenyl]sulfone, 2,2-bis[4-(4-aminophenoxy)phenyl]hexafluoropropane, bis[4-(4-aminophenoxy)phenyl]methane, 4,4′-bis(4-aminophenoxy)biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, 2,2′-bis(trifluoromethyl)biphenyl-4,4′-diamine, 2,6,2′,6′-tetramethyl-4,4′-diamine, 5,5′-dimethyl-2,2′-sulfonylbiphenyl-4,4′-diamine, 3,3′-dihydroxybiphenyl-4,4′-diamine, (4,4′-diamino)diphenyl ether, (4,4′-diamino)diphenylsulfone, (4,4′-diamino)benzophenone, (3,3′-diamino)benzophenone, (4,4′-diamino)diphenylmethane, (4,4′-diamino)diphenyl ether and (3,3′-diamino)diphenyl ether.

Hydrogen reduction of the aromatic diamine compound can be accomplished by an ordinary process for reduction of aromatic rings. As examples of reduction processes there may be mentioned hydrogen reduction in the presence of a catalyst such as a Raney nickel catalyst or platinum oxide catalyst (D. Varech et al., Tetrahedron Letter, 26, 61 (1985); R. H. Baker et al., J. Am. Chem. Soc., 69, 1250 (1947)), a rhodium-aluminum oxide catalyst (J. C. Sircar et al., J. Org. Chem., 30, 3206 (1965); A. I. Meyers et al., Organic Synthesis Collective Volume VI, 371 (1988); A. W. Burgstahler, Organic Synthesis Collective Volume V, 591 (1973); A. J. Briggs, Synthesis, 1988, 66), a rhodium oxide-platinum oxide catalyst (S. Nishimura, Bull. Chem. Soc. Jpn., 34, 32 (1961); E. J. Corey et al., J. Am. Chem. Soc. 101, 1608 (1979)), a charcoal-supported rhodium catalyst (K. Chebaane et al., Bull. Soc. Chim. Fr., 1975, 244) or a sodium borohydride-rhodium chloride-based catalyst (P. G Gassman et al., Organic Synthesis Collective Volume VI, 581 (1988); P. G Gassman et al., Organic Synthesis Collective Volume VI, 601 (1988)).

When the polyamideimide as component (C) is obtained using a diamine compound with a saturated hydrocarbon group as described above, it will contain a structural unit comprising a saturated hydrocarbon on the main chain of the polyamideimide. Such polyamideimides have very high water absorption resistance and water-repellency compared to conventional polyamideimides, due to the saturated hydrocarbon-containing structural unit. Furthermore, with an adhesive layer-attached conductive foil 100 wherein the adhesive layer 20 is a curable resin composition comprising a polyamideimide with a saturated hydrocarbon-containing structural unit, it is possible to significantly inhibit reduction in adhesion between the conductive foil (conductive layer) and insulating layer, for example, during moisture absorption when manufacturing a conductor-clad laminated sheet, compared to using a resin composition containing a polyamideimide with an aromatic ring. This effect is obtained more prominently when a diamine compound with an alicyclic saturated hydrocarbon group is used as the diamine compound with a saturated hydrocarbon group.

The polyamideimide used as component (C) may also be one obtained with further addition of a diamine compound other than a diamine compound with an alicyclic saturated hydrocarbon group, during the production stage. This will introduce into the polyamideimide a structural unit that does not have a structure with a saturated hydrocarbon, thus making it even easier to achieve desired properties.

As diamine compounds other than diamine compounds with a saturated hydrocarbon group there may be mentioned, first, compounds represented by the following general formula (3).

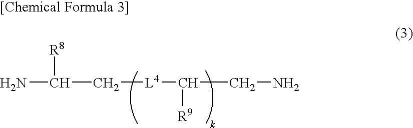

In formula (3), L⁴ represents a methylene, sulfonyl, oxo or carbonyl group or a single bond, R⁸ and R⁹ each independently represent hydrogen, alkyl or optionally substituted phenyl, and k represents an integer of 1-50.

In the diamine compounds represented by formula (3), preferably R⁸ and R⁹ each independently represent hydrogen, C1-3 alkyl or optionally substituted phenyl. Examples of substituents that may be bonded to the phenyl group include C1-3 alkyl groups, halogen atoms and the like. In the diamine compound represented by general formula (3), L⁴ is most preferably an oxy group from the viewpoint of achieving both a low elastic modulus and a high Tg. Specific examples of such diamine compounds include JEFFAMINE D-400 and JEFFAMINE D-2000 (both trade names of San Techno Chemical Co., Ltd.).

Aromatic ring-containing aromatic diamines are preferred diamine compounds to be combined with the diamine with a saturated hydrocarbon group. As aromatic diamines there may be mentioned compounds having two amino groups directly bonded to an aromatic ring, and compounds having two or more aromatic rings bonded together either directly or through a specific group, with an amino group bonded to each of at least two of these aromatic rings; there are no particular restrictions so long as such a structure is present.

As examples of aromatic diamine compounds there are preferred compounds represented by the following general formula (4a) or (4b).

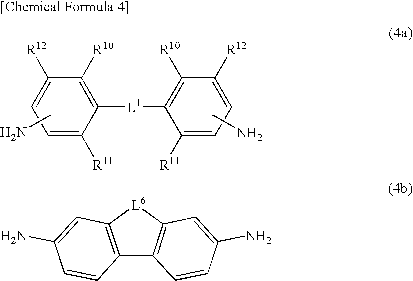

In formulas (4a) and (4b), L⁵ represents an optionally halogen-substituted C1-3 divalent aliphatic hydrocarbon group, a sulfonyl, oxy or carbonyl group, a single bond or a divalent group represented by the following formula (5a) or (5b), L⁶ represents an optionally halogen-substituted C1-3 divalent aliphatic hydrocarbon group or a sulfonyl, oxy or carbonyl group, and R¹⁰, R¹¹ and R¹² each independently represent hydrogen, hydroxyl, methoxy or an optionally halogen-substituted methyl group. L⁷ in the following formula (5a) represents an optionally halogen-substituted C1-3 divalent aliphatic hydrocarbon group, a sulfonyl, oxy or carbonyl group or a single bond.

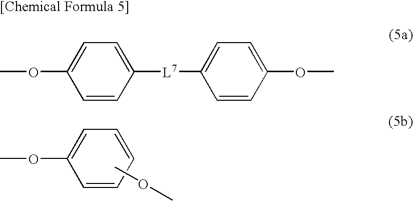

As aromatic diamines there may be mentioned, specifically, 2,2-bis[4-(4-aminophenoxy)phenyl]propane (BAPP), bis[4-(3-aminophenoxy)phenyl]sulfone, bis[4-(4-aminophenoxy)phenyl]sulfone, 2,2-bis[4-(4-aminophenoxy)phenyl]hexafluoropropane, bis[4-(4-aminophenoxy)phenyl]methane, 4,4′-bis(4-aminophenoxy)biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, 2,2′-bis(trifluoromethyl)biphenyl-4,4′-diamine, 2,6,2′,6′-tetramethyl-4,4′-diamine, 5,5′-dimethyl-2,2′-sulfonylbiphenyl-4,4′-diamine, 3,3′-dihydroxybiphenyl-4,4′-diamine, (4,4′-diamino)diphenyl ether, (4,4′-diamino)diphenylsulfone, (4,4′-diamino)benzophenone, (3,3′-diamino)benzophenone, (4,4′-diamino)diphenylmethane, (4,4′-diamino)diphenyl ether and (3,3′-diamino)diphenyl ether. Any one of these aromatic diamine compounds may be used alone, or two or more thereof may be used in combination.

Using such aromatic diamines will introduce an aromatic ring structure into the polyamideimide, in addition to the structural unit comprising a saturated hydrocarbon. A curable resin composition containing such a polyamideimide can yield cured products (and cured adhesive layers) with further improved Tg values, as well as even more satisfactory heat resistance.

As diamine compounds to be used with the saturated hydrocarbon group-containing diamine compound there are preferred siloxanediamines represented by the following general formula (6).

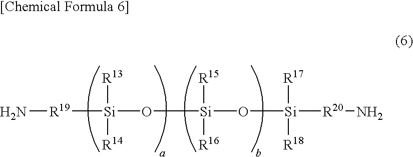

In formula (6), R¹³, R¹⁴, R¹⁵, R¹⁶, R¹⁷ and R¹⁸ (hereinafter referred to as “R¹³-R¹⁸”) preferably each independently represent a C1-3 alkyl or optionally substituted phenyl group. The substituent optionally bonded to the phenyl group is preferably a C1-3 alkyl group or a halogen atom. Preferably, R¹⁹ and R²⁰ each independently represent a C1-6 alkylene or optionally substituted arylene group. The arylene group is preferably an optionally substituted phenylene or optionally substituted naphthalene group. The substituent optionally bonded to the arylene group is preferably a C1-3 alkyl group or a halogen atom. In formula (6), a and b are each an integer of 1-15. Particularly preferable as such siloxanediamines are compounds wherein R¹³-R¹⁸ are methyl groups, i.e., which have a structure with amino groups bonded to both ends of the dimethylsiloxane. The siloxanediamine may be only one type of compound used alone, or it may be a combination of two or more different compounds.

Suitable commercially available siloxanediamines represented by general formula (6) above include, specifically, the silicone oils X-22-161AS (amine equivalents: 450), X-22-161A (amine equivalents: 840), X-22-161B (amine equivalents: 1500), X-22-9409 (amine equivalents: 700), X-22-1660B-3 (amine equivalents: 2200) (all trade names of Shin-Etsu Chemical Co., Ltd.), BY16-853 (amine equivalents: 650) and BY16-853B (amine equivalents: 2200) (both trade names of Toray Dow Corning Silicone Co., Ltd.).

Using a combination of the aforementioned siloxanediamines as diamine compounds will provide a siloxane structure on the main chain of the polyamideimide of component (C). Furthermore, a curable resin composition containing a polyamideimide with such a siloxane structure can form cured products with excellent flexibility and with very high resistance to swelling under high-temperature conditions, and can further enhance the durability and heat resistance of printed circuit boards obtained using this embodiment of the adhesive layer-attached conductive foil 100.

For production of a polyamideimide having a saturated hydrocarbon-containing structural unit, first diamine compounds including at least a diamine compound with a saturated hydrocarbon group are prepared as the diamine compounds. The diamine compounds are then reacted with trimellitic anhydride. Here, the amino groups of the diamine compounds react with the carboxyl or anhydrous carboxyl groups of the trimellitic anhydride to form amide groups. The reaction is preferably a reaction between the amino groups of the diamine compounds and anhydrous carboxyl groups of the trimellitic anhydride.

The reaction is preferably carried out at 70-100° C. after dissolving or dispersing the diamine compound and trimellitic anhydride in an aprotic polar solvent. Examples of aprotic polar solvents include N-methyl-2-pyrrolidone (NMP), γ-butyrolactone, N,N-dimethylformamide, N,N-dimethylacetamide, dimethyl sulfoxide, sulfolane and cyclohexanone. NMP is particularly preferred among these. These aprotic polar solvents may be used alone or in combinations of two or more.

The aprotic polar solvent is preferably used in an amount of 10-70 wt % and more preferably 20-60 wt %, as the solid content with respect to the total of the aprotic polar solvent, diamine compounds and trimellitic anhydride. If the solid content in the solution is less than 10 wt %, the amount of solvent will be too great and may pose a drawback for industrial use. If it exceeds 70 wt %, on the other hand, the solubility of the trimellitic anhydride will be lowered, potentially interfering with complete reaction.

An aromatic hydrocarbon that can form an azeotropic mixture with water is then added to the reacted solution and reaction is continued at 150-200° C. This produces dehydrating ring closure reaction between the carboxyl groups and amide groups, thus yielding an imide group-containing dicarboxylic acid. Examples of aromatic hydrocarbons that can form azeotropic mixtures with water include toluene, benzene, xylene and ethylbenzene. Toluene is preferred among these. The aromatic hydrocarbon is preferably added in an amount corresponding to 10-50 parts by weight with respect to 100 parts by weight of the aprotic polar solvent. If the aromatic hydrocarbon is added in an amount of less than 10 parts by weight with respect to 100 parts by weight of the aprotic polar solvent, the water-removal effect will tend to be insufficient and the production yield of the imide group-containing dicarboxylic acid will tend to be reduced. If it is greater than 50 parts by weight, on the other hand, the reaction temperature of the solution will be lowered, thus tending to reduce the production yield of the imide group-containing dicarboxylic acid.

By distilling off the aromatic hydrocarbon in the solution together with water during the dehydrating ring closure reaction, it is often possible to reduce the amount of aromatic hydrocarbon in the reaction mixture even to below the aforementioned preferred range. For example, the water and aromatic hydrocarbon may be distilled off into a cock-equipped water measuring receptacle, and the aromatic hydrocarbon separated out and returned to the reaction mixture, in order to maintain a fixed proportion of the aromatic hydrocarbon in the reaction mixture. Upon completion of the dehydrating ring closure reaction, the temperature of the solution is preferably held at about 150-200° C. to remove the aromatic hydrocarbon that forms an azeotropic mixture with water.

The imide group-containing dicarboxylic acid obtained by the reaction to this point has a structure represented by the following general formula (7), for example.

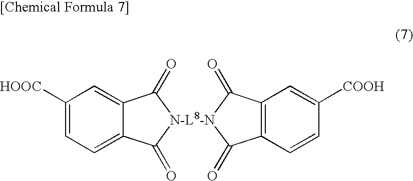

In formula (7), L⁸ represents the residue obtained after removing the amino groups from a diamine compound represented by any of general formulas (1a), (1b), (3), (4a), (4b) or (6) above. Thus, the imide group-containing dicarboxylic acid may be obtained as any of various compounds wherein L⁸ has a structure corresponding to the diamine compound used as the starting material.

The method for synthesizing a polyamideimide using an imide group-containing dicarboxylic acid obtained in this manner may be one of the following methods. Specifically, as a first method, the imide group-containing dicarboxylic acid is converted to an acid halide and then copolymerized with one of the diamine compounds mentioned above.

The imide group-containing dicarboxylic acid can be easily converted to an acid halide by reaction with thionyl chloride or with phosphorus trichloride, phosphorus pentachloride or dichloromethyl methyl ether. The halide of the imide-containing dicarboxylic acid obtained in this manner can then be easily copolymerized with the diamine compound at room temperature or under heated conditions.

As a second method, the imide group-containing dicarboxylic acid may be copolymerized with one of the aforementioned diamine compounds in the presence of a condensation agent. In this reaction, the condensation agent may be any condensation agent commonly used to form amide bonds. Preferred among such agents are dicyclohexylcarbodiimide, diisopropylcarbodiimide and N-ethyl-N′-3-dimethylaminopropylcarbodiimide, used either alone or in combination with N-hydroxysuccinimide or 1-hydroxybenzotriazole.

As a third method, the imide group-containing dicarboxylic acid may be reacted with a diisocyanate. When this reaction is employed, the ratio between the diisocyanate and the diamine compound and trimellitic anhydride as the starting materials for the imide group-containing dicarboxylic acid is preferably set as follows. That is, (diamine compound:trimellitic anhydride:diisocyanate) is preferably in the range of 1.0:(2.0-2.2):(1.0-1.5) and more preferably in the range of 1.0:(2.0-2.2):(1.0-1.3), in terms of molar ratio. Preparation with this molar ratio can yield a polyamideimide that is advantageous for higher molecular weight film formation.

The diisocyanate used for the third method may be a compound represented by the following general formula (8).

[Chemical Formula 8]

OCN-L⁹-NCO (8)

In formula (8), L⁹ is a divalent organic group with at least one aromatic ring, or a divalent aliphatic hydrocarbon group. It is preferably at least one group selected from among groups represented by the following formula (9a), groups represented by the following formula (9b), and tolylene, naphthylene, hexamethylene and 2,2,4-trimethylhexamethylene groups.

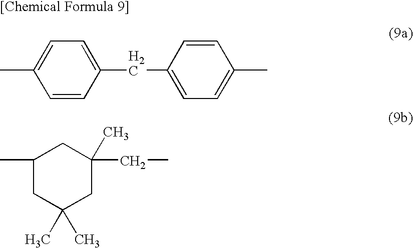

As diisocyanates represented by general formula (8) there may be mentioned aliphatic diisocyanates and aromatic diisocyanates, with aromatic diisocyanates being preferred, and most preferably both types are used together. Examples of aromatic diisocyanates include 4,4′-diphenylmethane diisocyanate (MDI), 2,4-tolylene diisocyanate, 2,6-tolylene diisocyanate, naphthalene-1,5-diisocyanate and 2,4-tolylene dimer. MDI is particularly preferred among these. Using MDI as an aromatic diisocyanate can improve the flexibility of the obtained polyamideimide and also reduce the crystallinity. The film formability of the polyamideimide can be further improved as a result. Examples of aliphatic diisocyanates, on the other hand, include hexamethylene diisocyanate, 2,2,4-trimethylhexamethylene diisocyanate and isophorone diisocyanate.

When an aromatic diisocyanate and aliphatic diisocyanate are used in combination, the aliphatic diisocyanate is preferably added at about 5-10 molar parts with respect to 100 molar parts of the aromatic diisocyanate. This can still further improve the heat resistance of the polyamideimide.

The reaction between the imide group-containing dicarboxylic acid and the diisocyanate in the third method may be carried out by adding the diisocyanate to a solution containing the imide group-containing dicarboxylic acid and conducting reaction at a temperature of 130-200° C. The reaction may also be carried out using a basic catalyst. In this case, the reaction temperature is preferably 70-180° C. and more preferably 120-150° C. Conducting the reaction in the presence of a basic catalyst will allow the reaction to proceed at a lower temperature than if it is conducted in the absence of a basic catalyst, and can therefore inhibit secondary reactions such as reaction among the diisocyanate compounds under high-temperature conditions. As a result, it will be possible to obtain a higher molecular weight polyamideimide compound.

Examples of basic catalysts include trialkylamines such as trimethylamine, triethylamine, tripropylamine, tri(2-ethylhexyl)amine and trioctylamine. Of these, triethylamine is especially preferred because it is a suitable basic catalyst for promoting the aforementioned reactions and because it is easy to remove from the system after the reaction.

The polyamideimides obtained by the various methods described above may have structural units represented by the following general formula (10), for example. L⁸ and L⁹ in the following formula (10) have the same definitions as L⁸ and L⁹ above.

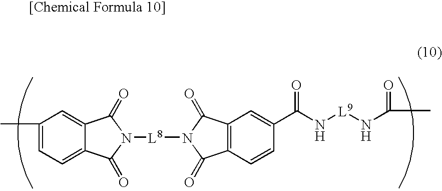

A curable resin composition according to a preferred embodiment is one comprising components (A) to (C) described above. Components (A) to (C) are preferably present in such a curable resin composition in a mixing proportion that satisfies the following conditions.

First, the mixing proportion of component (B) in the curable resin composition is preferably 0.5-200 parts by weight and more preferably 10-150 parts by weight with respect to 100 parts by weight of component (A). If the mixing proportion of component (B) is less than 0.5 part by weight, the toughness of the adhesive cured layer and its adhesion with the conductive foil (conductive layer) will tend to be reduced in the adhesive layer-attached conductive foil 100 or in a printed circuit board obtained using it. If it exceeds 200 parts by weight, on the other hand, the thermosetting property of the adhesive layer 20 will be reduced and the reactivity between the adhesive cured layer and insulating resin layer will be lower, potentially leading to lower heat resistance, chemical resistance and breaking strength of the adhesive cured layer itself, or near the interface between the adhesive cured layer and insulating resin layer, when a conductor-clad laminated sheet or printed circuit board is formed as described hereunder.

The mixing proportion of component (C) is preferably 10-400 parts by weight with respect to 100 parts by weight as the total of component (A) and component (B). If the mixing proportion of component (C) is less than 10 parts by weight, the toughness of the adhesive cured layer and its adhesion with the conductive foil (conductive layer) will tend to be reduced in the adhesive layer-attached conductive foil 100 or in a printed circuit board obtained using it. If it exceeds 400 parts by weight, the heat resistance, chemical resistance and breaking strength of the adhesive cured layer itself or near the interface between the adhesive cured layer and insulating resin layer will tend to be reduced.

The curable resin composition composing the adhesive layer 20 may further contain desired components as necessary, in addition to components (A) to (C) mentioned above. As components other than components (A) to (C) there may be mentioned, first, curing accelerators with a catalytic function to promote reaction between the polyfunctional epoxy resin as component (A) and the polyfunctional phenol resin as component (B). As examples of curing accelerators there may be mentioned, without any particular restrictions, amine compounds, imidazole compounds, organo-phosphorus compounds, alkali metal compounds, alkaline earth metal compounds and quaternary ammonium salts. These curing accelerators may be used alone or in combinations of two or more.

The mixing proportion of the curing accelerator in the curable resin composition is preferably established based on the mixing proportion of component (A). Specifically, it is preferably 0.05-10 parts by weight with respect to 100 parts by weight of component (A). Addition of a curing accelerator within this range will result in a satisfactory reaction rate between component (A) and component (B), and provide even more excellent reactivity and curability of the curable resin composition for the adhesive layer 20. As a result, the cured layer (adhesive cured layer) obtained from the adhesive layer 20 will exhibit even more excellent chemical resistance, heat resistance and humid heat resistance.

As a component in addition to components (A) to (C), it is preferred to add (D1) crosslinked rubber particles and/or (D2) a polyvinylacetal resin, as component (D).

Particularly preferred as component (D) are (D1) crosslinked rubber particles. As crosslinked rubber particles there may be suitably used one or more types selected from among acrylonitrile-butadiene rubber particles, carboxylic acid-modified acrylonitrile-butadiene rubber particles and butadiene rubber-acrylic resin core-shell particles.

Acrylonitrile-butadiene rubber particles are obtained by copolymerizing acrylonitrile and butadiene, with partial crosslinking during the copolymerization stage, to form particles. Carboxylic acid-modified acrylonitrile-butadiene rubber particles are obtained by including a carboxylic acid such as acrylic acid or methacrylic acid during the copolymerization. Butadiene rubber-acrylic resin core-shell particles are obtained by a two-stage polymerization process involving polymerization of butadiene particles by emulsion polymerization, followed by addition of a monomer such as an acrylic acid ester or acrylic acid for continued polymerization. The sizes of the crosslinked rubber particles are preferably 50 nm-1 μm, as the primary mean particle size. Any of the aforementioned crosslinked rubber particles may be added alone, or two or more different types may be added in combination.

More specifically, XER-91 by JSR Corp. may be mentioned as carboxylic acid-modified acrylonitrile-butadiene rubber particles, among such crosslinked rubber particles. As butadiene rubber-acrylic resin core-shell particles there may be mentioned EXL-2655 by Kureha Corp. and AC-3832 by Takeda Pharmaceutical Co., Ltd.

More preferred as component (D) is a polyvinylacetal resin (D2). It is particularly preferred to use (D1) crosslinked rubber particles and (D2) a polyvinylacetal resin as component (D), in order to improve the peel strength of the adhesive cured layer with respect to the conductive foil, and to improve the peel strength for electroless plating after chemical roughening.

As polyvinylacetal resins for component (D2) there may be mentioned polyvinylacetals and their carboxylic acid-modified forms, which are carboxylic acid-modified polyacetal resins. Various polyvinylacetal resins with different hydroxyl and acetyl group contents may be used without any particular restrictions, but a polymerization degree of 1000-2500 is preferred. A polyvinylacetal resin with a polymerization degree in this range will ensure adequate soldering heat resistance of the adhesive cured layer. Also, varnishes containing the curable resin composition will have satisfactory viscosity and manageability and production of the adhesive layer-attached conductive foil 20 will tend to be facilitated.

The value for the number-average polymerization degree of the polyvinylacetal resin may be determined from the number-average molecular weight of the polyvinyl acetate starting material (measured by gel permeation chromatography using a calibration curve for standard polystyrene). A carboxylic acid-modified polyvinylacetal resin is the carboxylic acid-modified form of the aforementioned polyvinylacetal resin, and preferably it satisfies the same conditions as the polyvinylacetal resin.

As examples of polyvinylacetal resins there may be mentioned S-LEC BX-1, BX-2, BX-5, BX-55, BX-7, BH-3, BH-S, KS-3Z, KS-5, KS-5Z, KS-8 and KS-23Z, trade names of Sekisui Chemical Industries, Ltd., and DENKA BUTYRAL 4000-2, 5000A, 6000C and 6000EP, trade names of Denki Kagaku Kogyo Co., Ltd. Any of the aforementioned polyvinylacetal resins may be used alone, or two or more thereof may be used in admixture.

The mixing proportion of component (D) in the curable resin composition is preferably in the range of 0.5-100 parts by weight and more preferably 1-50 parts by weight with respect to 100 parts by weight as the total of component (A) and component (B). If the mixing proportion of component (D) is less than 0.5 part by weight, the toughness of the adhesive cured layer and adhesion of the adhesive cured layer with the conductive foil (conductive layer) will tend to be reduced in the adhesive layer-attached conductive foil 100 or in a printed circuit board obtained using it. If it exceeds 100 parts by weight, on the other hand, the heat resistance, chemical resistance and breaking strength of the adhesive cured layer itself or near the interface between the adhesive cured layer and insulating resin layer will tend to be reduced. When multiple different components are included as component (D), their total is preferably such as to satisfy the mixing proportion mentioned above.

Depending on the desired properties, the curable resin composition may contain various additives such as flame retardants, fillers and coupling agents, in amounts that do not impair the properties such as heat resistance, adhesion and water absorption resistance provided by the cured layer composed of the adhesive layer 20, when the composition is used in formation of a printed circuit board.

There are no particular restrictions on flame retardants, and bromine-based, phosphorus-based and metal hydroxide flame retardants are suitable for use. More specifically, as bromine-based flame retardants there may be mentioned brominated additive flame retardants including brominated epoxy resins such as brominated bisphenol A-type epoxy resin and brominated phenol-novolac-type epoxy resin, and hexabromobenzene, pentabromotoluene, ethylenebis(pentabromophenyl), ethylenebistetrabromophthalimide, 1,2-dibromo-4-(1,2-dibromoethyl)cyclohexane, tetrabromocyclooctane, hexabromocyclododecane, bis(tribromophenoxy)ethane, brominated polyphenylene ether, brominated polystyrene, 2,4,6-tris(tribromophenoxy)-1,3,5-triazine and the like, and brominated reactive flame retardants containing unsaturated double bonds, such as tribromophenylmaleimide, tribromophenyl acrylate, tribromophenyl methacrylate, tetrabromobisphenol A-type dimethacrylate, pentabromobenzyl acrylate and brominated styrene.

Examples of phosphorus-based flame retardants include aromatic phosphoric acid esters such as triphenyl phosphate, tricresyl phosphate, trixylenyl phosphate, cresyl diphenylphosphate, cresyl di-2,6-xylenylphosphate and resorcinol bis(diphenylphosphate), phosphonic acid esters such as divinyl phenylphosphonate, diallyl phenylphosphonate and (1-butenyl)phenylphosphonate, phosphinic acid esters such as phenyl diphenylphosphinate, methyl diphenylphosphinate and 9,10-dihydro-9-oxa-10-phosphaphenanthrene-10-oxide derivatives, phosphazene compounds such as bis(2-allylphenoxy)phosphazene and dicresylphosphazene, and melamine phosphate, melamine pyrophosphate, melamine polyphosphate, melam polyphosphate, ammonium polyphosphate, red phosphorus and the like. Examples of metal hydroxide flame retardants include magnesium hydroxide and aluminum hydroxide. Such flame retardants may be used alone or in combinations of two or more different types.

When a flame retardant is added, its mixing proportion is not particular restricted but is preferably 5-150 parts by weight, more preferably 5-80 parts by weight and even more preferably 5-60 parts by weight with respect to 100 parts by weight as the total of component (A) and component (B). If the mixing proportion of the flame retardant is less than 5 parts by weight, the flame resistance of the adhesive layer 20 or adhesive cured layer will tend to be insufficient. If it exceeds 100 parts by weight, on the other hand, the heat resistance of the adhesive cured layer will tend to be reduced.

There are no particular restrictions on filler additives, but inorganic fillers are preferred. As examples of inorganic fillers there may be mentioned alumina, titanium oxide, mica, silica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clays such as calcined clay, talc, aluminum borate, aluminum borate, silicon carbide, and the like.

Such fillers may be used alone or in combinations of two or more. There are also no particular restrictions on the form and particle size of the filler, but the particle size is preferably 0.01-50 μm and more preferably 0.1-15 μm. The mixing proportion of a filler in the curable resin composition is preferably, for example, 1-1000 parts by weight and more preferably 1-800 parts by weight with respect to 100 parts by weight as the total of component (A) and component (B).

There are no particular restrictions on coupling agents, and as examples there may be mentioned silane-based coupling agents and titanate-based coupling agents. Carbon functional silanes may be mentioned as examples of silane-based coupling agents. Specifically, there may be mentioned epoxy group-containing silanes such as 3-glycidoxypropyltrimethoxysilane, 3-glycidoxypropyl(methyl)dimethoxysilane and 2-(2,3-epoxycyclohexyl)ethyltrimethoxysilane; amino group-containing silanes such as 3-aminopropyltriethoxysilane, N-(2-aminoethyl)-3-aminopropyltrimethoxysilane and N-(2-aminoethyl)-3-aminopropyl(methyl)dimethoxysilane; cationic silanes such as 3-(trimethoxysilyl)propyltetramethylammonium chloride, vinyl group-containing silanes such as vinyltriethoxysilane, acrylic group-containing silanes such as 3-methacryloxypropyltrimethoxysilane; and mercapto group-containing silanes such as 3-mercaptopropyltrimethoxysilane. As examples of titanate-based coupling agents there may be mentioned titanic acid alkyl esters such as titanium propoxide and titanium butoxide. Such coupling agents may be used alone or in combinations of two or more.

The mixing proportion of a coupling agent in the curable resin composition is not particularly restricted but is preferably 0.05-20 parts by weight and more preferably 0.1-10 parts by weight with respect to 100 parts by weight as the total of component (A) and component (B). A curable resin composition containing the components mentioned above may be prepared by combining and mixing component (A), component (B), component (C) and the other additives by known methods.

### [Process for Production of Adhesive Layer-Attached Conductive Foil]

A preferred process for production of the adhesive layer-attached conductive foil 100 having the structure described above will now be explained. The adhesive layer-attached conductive foil 100 may be obtained, for example, by first preparing the curable resin composition and coating it, or a varnish obtained by dissolving or dispersing it in a solvent, onto the M-surface 12 of the aforementioned conductive foil 10, and then drying it to form an adhesive layer 20. The curable resin composition may also be subjected to semi-curing (B-staging).

Coating of the curable resin composition or its varnish may be accomplished by a known method using, for example, a kiss coater, roll coater, comma coater, gravure coater or the like. Drying may be accomplished by method of treatment in a heated drying furnace, for example, at a temperature of 70-250° C. and preferably 100-200° C., for 1-30 minutes and preferably 3-15 minutes. When a solvent is used for dissolution of the curable resin composition, the drying temperature is preferably above the temperature which allows volatilization of the solvent.

There are no particular restrictions on the solvent used to form a varnish of the curable resin composition, and as examples there may be mentioned alcohols such as methanol, ethanol and butanol, ethers such as ethylcellosolve, butylcellosolve, ethyleneglycol monomethyl ether, carbitol and butylcarbitol, ketones such as acetone, methyl ethyl ketone, methyl isobutyl ketone and cyclohexanone, aromatic hydrocarbons such as toluene, xylene and mesitylene, esters such as methoxyethyl acetate, ethoxyethyl acetate, butoxyethyl acetate and ethyl acetate, and nitrogen-containing compounds such as N,N-dimethylformamide, N,N-dimethylacetamide and N-methyl-2-pyrrolidone. These solvents for varnishes may be used alone or in combinations of two or more.

When nitrogen-containing compounds and ketones are used together among the solvents mentioned above, their mixing proportions are preferably 1-500 parts by weight of ketones, more preferably 3-300 parts by weight of ketones and even more preferably 5-250 parts by weight of ketones with respect to 100 parts by weight of nitrogen-containing compounds.

When the curable resin composition is used as a varnish, the amount of solvent is preferably adjusted for a solid (nonvolatile) concentration of 3-80 wt % for the varnish. Appropriately varying the amount of solvent during fabrication of the adhesive layer-attached conductive foil 100 will facilitate adjustment of the solid concentration and varnish viscosity to obtain an adhesive layer 20 having the preferred film thickness mentioned above.

The adhesive layer-attached conductive foil 100 having such a construction is laminated on the insulating resin layer via the adhesive layer 20, thus allowing easy formation of a conductor-clad laminated sheet or the like. Since the conductor-clad laminated sheet or the like obtained in this manner has the conductive foil 1 and insulating resin layer bonded via the cured adhesive layer 20 (adhesive cured layer), it is possible to achieve excellent peel strength for conductors (conductive foils), even when a low permittivity resin such as polybutadiene, triallyl cyanurate, triallyl isocyanurate or a functionalized polyphenylene ether is used as the material for the insulating resin layer. Furthermore, the peel strength is adequately maintained even during moisture absorption. As a result the conductor-clad laminated sheet is highly resistant to interlayer peeling and the properties can be satisfactorily maintained even during moisture absorption.

These properties can be adequately exhibited even when the adhesive layer-attached conductive foil 100 has a conductive foil 10 with relatively low M-surface roughness. A printed circuit board or the like obtained using the conductor-clad laminated sheet, therefore, is satisfactory in terms of high-frequency property, conductive layer adhesion and heat resistance. The adhesive layer-attached conductive foil 100 of this embodiment is therefore suitable as a conductor-clad laminated sheet member or material for formation of printed circuit boards and the like provided in various electric and electronic devices that handle high-frequency signals.

### [Conductor-Clad Laminated Sheet and Process for its Production]

Preferred embodiments of conductor-clad laminated sheets and a process for their production will now be explained.

### First Example

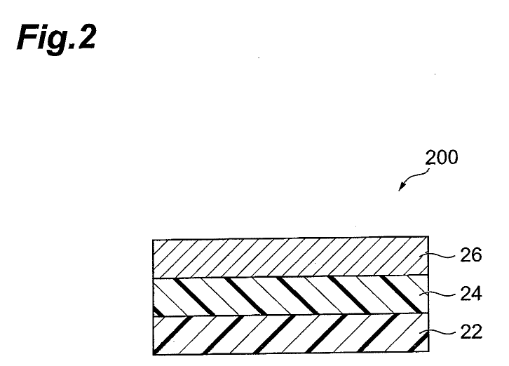

FIG. 2 shows the partial cross-sectional construction of a conductor-clad laminated sheet according to a first example. The conductor-clad laminated sheet 200 shown in FIG. 2 has a laminated structure with an insulating layer 22, adhesive cured layer 24 and conductive layer 26 in that order.

In the conductor-clad laminated sheet 200, a prescribed number of known prepregs, for example, are attached together and then heated and/or pressed to obtain the insulating layer 22. The prepregs used may be fabricated by a known process involving impregnating a resin varnish into a woven fabric or nonwoven fabric made of fibers composed of at least one material selected from the group consisting of glass, paper and organic high molecular compounds. Examples of fibers composed of glass (glass fibers) include E glass, S glass, NE glass, D glass and Q glass. Examples of fibers composed of organic high molecular compounds (organic fibers) include aramids, fluorine-based resins, polyesters and liquid crystalline polymers. These may be used as single compounds or as combinations of two or more compounds.

As resins for the resin varnish there are preferred resins with an insulating property (insulating resins), and resins with ethylenic unsaturated bonds are more preferred. As such insulating resins there may be mentioned polybutadiene, polytriallyl cyanurate, polytriallyl isocyanurate, unsaturated group-containing polyphenylene ethers with a structural unit containing an ethylenic unsaturated bond, and maleimide compounds. These insulating resins have low relative permittivities and dielectric loss tangents, and can therefore reduce the transmission loss of a circuit board obtained from the conductor-clad laminated sheet 200. These may be used as single compounds or as combinations of two or more compounds.

The insulating resin also preferably contains at least one compound selected from the group consisting of polyphenylene ethers and thermoplastic elastomers, with saturated thermoplastic elastomers being especially preferred as thermoplastic elastomers. These resins have low permittivity and low dielectric loss tangents, and can therefore drastically reduce the dielectric loss.

A maleimide compound (polymaleimide) as the insulating resin may be a resin with a maleimide backbone on the main chain, or a resin with a maleimide group on a side chain and/or an end. However, it is preferably a maleimide compound used as a crosslinking aid for the insulating resin. This will not only reduce the transmission loss of a circuit board obtained from the conductor-clad laminated sheet 200, but will also improve the curability, thus resulting in a more satisfactory coefficient of thermal expansion and heat resistance of the resin. The insulating layer 22 preferably has a relative permittivity of no greater than 4.0 at 1 GHz. An insulating layer 22 satisfying this condition will help to significantly reduce the dielectric loss. A printed circuit board 200 obtained from such a conductor-clad laminated sheet will therefore have very low transmission loss.

The conductive layer 26 used may one that is ordinarily used as a conductive layer for printed circuit boards, without any particular restrictions. Examples of such conductive layers 26 include those consisting of conductive foils, and specifically metal foils. As metal foils there may be used the ones mentioned above as examples for the conductive foil 10 of the adhesive layer-attached conductive foil 100.

The adhesive cured layer 24 is a layer comprising the cured product of a curable resin composition which contains component (A): a polyfunctional epoxy resin, component (B): a polyfunctional phenol resin and component (C): a polyamideimide. The curable resin composition (before curing) in the adhesive cured layer 24 may be the same as the curable resin composition in the adhesive layer 20 of the adhesive layer-attached conductive foil 100 described above.

The conductor-clad laminated sheet 200 having this construction may be fabricated by the following production process, for example, when using the aforementioned adhesive layer-attached conductive foil 100.

First, an adhesive layer-attached conductive foil 100 is prepared in the manner described above. The adhesive layer 20 in the adhesive layer-attached conductive foil 100 corresponds to the adhesive cured layer 24 before curing. A prepreg is also prepared for formation of the insulating layer 22. The prepreg may be fabricated by a known method, such as impregnation of the insulating resin into reinforcing fibers such as glass fibers or organic fibers, and semi-curing of the resin.

A prescribed number of such prepregs are stacked to form an insulating resin film. The adhesive layer-attached conductive foil 100 is stacked on one side of the insulating resin film with the adhesive layer 20 in contact with the insulating resin film. It is then heated and/or pressed to obtain a conductor-clad laminated sheet 200. The heating and pressing results in curing of the resin with an insulating property that is in the insulating resin film, simultaneously with curing of the curable resin composition composing the adhesive layer 20. As a result, an insulating layer 22 is formed from the insulating resin film and an adhesive cured layer 24 is formed from the adhesive layer 20.

The heating is preferably carried out at a temperature of 150-250° C., and the pressing is preferably at a pressure of 0.5-10.0 MPa. The heating/pressing time is preferably 0.5-10 hours. The heating and pressing may be carried out simultaneously using a vacuum press, for example. This will allow curing of the adhesive layer 20 and insulating resin film to proceed sufficiently, to achieve excellent adhesion between the conductive layer 26 and insulating layer 22 by the adhesive cured layer 24, and to obtain a conductor-clad laminated sheet 200 with excellent chemical resistance, heat resistance and humid heat resistance.

### Second Example

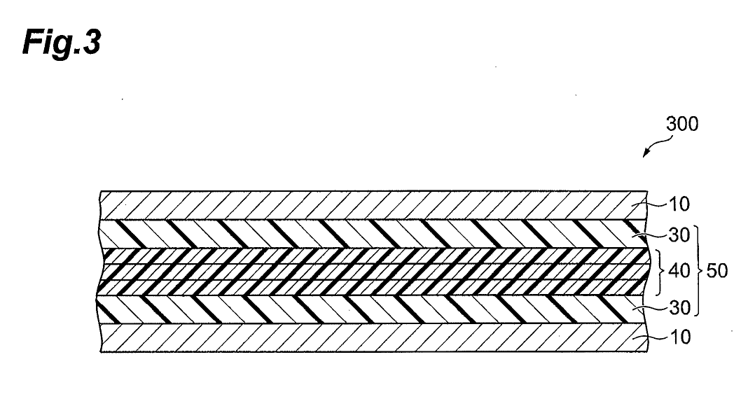

FIG. 3 shows the partial cross-sectional construction of a conductor-clad laminated sheet according to a second example. The conductor-clad laminated sheet 300 of the second example has a construction with conductive layers formed on both sides of the insulating layer, unlike the conductor-clad laminated sheet 200 described above.

The conductor-clad laminated sheet 300 shown in FIG. 2 has a construction provided with an insulating resin layer 40, adhesive cured layers 30 laminated on both sides of the insulating resin layer 40, and conductive foils 10 laminated on the sides of the adhesive cured layers 30 opposite the insulating resin layer 40.

The insulating resin layer 40 has a construction comprising a plurality of integral laminated layers. The insulating resin layer 40 may be the same type as the insulating layer 22 of the conductor-clad laminated sheet 200 used in the first example described above. In this conductor-clad laminated sheet 300, the insulating resin layer 40 and adhesive cured layers 30 become integrated to form an insulating layer 50.

The conductive foils 10 and adhesive cured layers 30 of the conductor-clad laminated sheet 300 having this construction are formed from the adhesive layer-attached conductive foil 100 of the embodiment described above. That is, the adhesive cured layers 30 are cured layers obtained by curing the adhesive layer 20 of the adhesive layer-attached conductive foil 100, and the conductive foils 10 are each composed of a conductive foil 10 of the adhesive layer-attached conductive foil 100.

The conductor-clad laminated sheet 300 according to the second example can be obtained in the following manner, for example. First, an insulating resin film is prepared as in the first example. Next, a pair of adhesive layer-attached conductive foils 100 are stacked on both sides of the insulating resin film with their respective adhesive layers 20 in contact with the insulating resin film. The stack is then heated and/or pressed to obtain a conductor-clad laminated sheet 300. The heating and pressing results in curing of the resin with an insulating property in the insulating resin film, simultaneously with curing of the curable resin composition composing the adhesive layers 20. As a result, insulating resin layers 40 are formed from the insulating resin film and adhesive cured layers 30 are formed from the adhesive layers 20.

The heating and pressing conditions during this time may be the same conditions as for the first example described above. This will allow curing of the adhesive layers 20 and insulating resin film to proceed sufficiently, to achieve excellent adhesion between the conductive foil 10 and the insulating layer 50, and to obtain a conductor-clad laminated sheet 300 with excellent chemical resistance, heat resistance and humid heat resistance.

The conductor-clad laminated sheet 300 obtained in this manner has the construction described above, i.e. it has a structure wherein an insulating layer 50 composed of the integrated insulating resin layer 40 and adhesive cured layers 30, is sandwiched between conductive foils 10. The conductor-clad laminated sheet 300 is formed using adhesive layer-attached conductive foils 100. It is therefore advantageous for fabricating printed circuit boards that can adequately inhibit transmission loss in the high-frequency band, and also has sufficiently high adhesion between the insulating layer 50 and conductive foils 10.

### [Printed Circuit Board and Process for its Production]

Preferred embodiments of printed circuit boards and a process for their production will now be explained. The printed circuit boards can be used as ordinary printed circuit boards.

### First Example

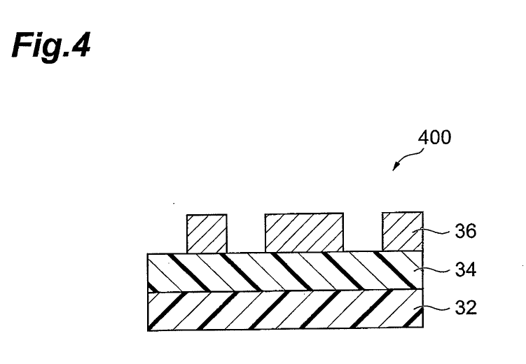

FIG. 4 shows the partial cross-sectional construction of a printed circuit board according to a first example. The printed circuit board 400 shown in FIG. 4 has a construction provided with an insulating layer 32, an adhesive cured layer 34 and a circuit pattern 36, in that order. The printed circuit board 400 is preferably obtained using a conductor-clad laminated sheet 200 according to the first example described above. Specifically, the insulating layer 32, adhesive cured layer 34 and circuit pattern 36 are composed of the same materials as the insulating layer 22, adhesive cured layer 24 and conductive layer 26 in the conductor-clad laminated sheet 200, respectively.

The printed circuit board 400 having this construction may be produced, for example, by working the conductive layer 26 of the conductor-clad laminated sheet 200 into a desired circuit pattern by a known etching process.

### Second Example

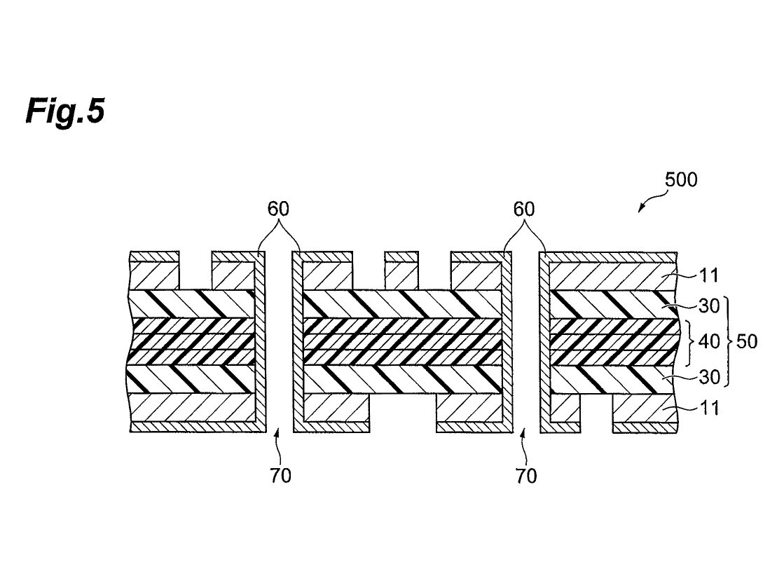

FIG. 5 shows the partial cross-sectional construction of a printed circuit board according to a second example. The printed circuit board 500 shown in FIG. 5 is preferably obtained using a conductor-clad laminated sheet 300 according to the second example described above, and it has a construction provided with circuit patterns on both sides.

The printed circuit board 500 has a construction provided with an insulating resin layer 40, adhesive cured layers 30 laminated on both sides of the insulating resin layer 40, and circuit patterns 11 (conductive layers) formed on the sides of the adhesive cured layers 30 opposite the insulating resin layer 40. Also, through-holes 70 running in the lamination direction are provided at prescribed locations of the printed circuit board 500, and a plated coating 60 is formed on their side walls and on the surface of the circuit pattern 11. The plated coating 60 establishes connection between the front and back circuit patterns 11. In this printed circuit board 500, the adhesive cured layers 30 and insulating resin layer 40 have the same respective construction as the adhesive cured layers 30 and insulating resin layer 40 of the conductor-clad laminated sheet 300 described above. The adhesive cured layers 30 and insulating resin layer 40 are also integrally formed, composing an insulating layer 50 that functions as the base. The printed circuit board 500 having this construction is preferably produced in the following manner, for example.

Specifically, a conductor-clad laminated sheet 300 according to the embodiment described above is prepared. The conductor-clad laminated sheet 300 is then drilled and plated by known processes. The through-holes 70 and plated coating 60 are thus formed. The conductive foils 10 on the surfaces of the conductor-clad laminated sheet 300 are worked into prescribed circuit shapes by a known process such as etching. Circuit patterns 11 are thus formed from the conductive foils 10. This produces a printed circuit board 500.

The printed circuit board 500 is formed from the conductor-clad laminated sheet 300 obtained using the adhesive layer-attached conductive foil 100. Thus, the circuit patterns 11 obtained from the conductive foils 10 in the printed circuit board 500 are firmly bonded to the insulating resin layer 40 via the adhesive cured layers 30. In other words, very satisfactory adhesion is achieved between the circuit patterns 11 and insulating layer 50. Therefore, very little peeling of the circuit patterns 11 from the insulating layer 50 occurs, even when low-roughened foils are used as the conductive foils 10 to form the circuit patterns 11. The printed circuit board 500 also has low transmission loss in the high-frequency band.

Moreover, peeling of the circuit patterns 11 is also adequately reduced even when the resin material used in the insulating resin layer 40 is a resin with a high insulating property and high heat resistance. The adhesive cured layer 30 can also maintain excellent adhesion even under high humidity conditions. Consequently, the printed circuit board 500 is capable of handling even higher frequencies because of the excellent insulating property of the insulating layer 50, while it also exhibits excellent heat resistance, especially heat resistance under highly humid conditions.

### [Multilayer Interconnection Board and Process for its Production]

Preferred embodiments of multilayer interconnection boards and a process for their production will now be explained.

### First Example

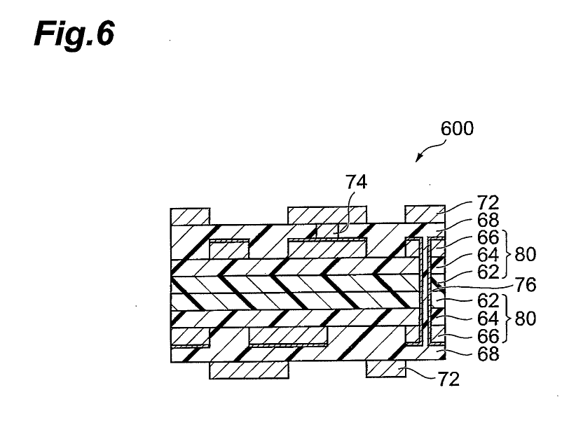

FIG. 6 shows the partial cross-sectional construction of a multilayer interconnection board according to a first example. The multilayer interconnection board 600 shown in FIG. 6 has a structure wherein a pair of circuit boards each comprising an insulating layer 62, adhesive cured layer 64, inner circuit pattern 66, interlayer insulating layer 68 and outer circuit pattern 72 in that order, are attached together with their insulating layers 62 facing each other. In this multilayer interconnection board 600, the inner circuit patterns 66 and outer circuit patterns 72 are connected by a via hole 74 formed in the interlayer insulating layer 68. The inner circuit patterns 66 of the pair of circuit boards are connected a through-hole 76.

The insulating layers 62, adhesive cured layers 64 and inner circuit patterns 66 of the multilayer interconnection board 600 are composed of the same materials as the insulating layer 32, adhesive cured layer 34 and circuit pattern 36 of the printed circuit board 400, respectively. That is, the multilayer interconnection board 600 employs the aforementioned printed circuit board 400 as core boards 80. For each of the interlayer insulating layers 68, there may be used a layer composed of a known resin material with an insulating property (for example, the resin material in the insulating layer 32 of the printed circuit board 400), or a layer composed of a prepreg having a prescribed toughened base in an insulating resin material.

The outer circuit patterns 72 are composed of the same conductive material as the inner circuit patterns 66. The via hole 74 or through-hole 76 allows conduction at prescribed locations between the inner circuit patterns 66 and outer circuit patterns 72, or between the inner circuit patterns 66.

The multilayer interconnection board 600 having this construction may be produced by the following method. Specifically, a pair of printed circuit boards 400 are first prepared as core boards 80, and they are stacked with their insulating layers 32 facing each other. If necessary they are perforated and metal plated to form the through-hole 76. Next, a prescribed number of prepregs for the interlayer insulating layers 68 are stacked on the circuit pattern 36 (inner circuit pattern 66) of each printed circuit board 400.

A hole is then formed at a prescribed location of the prepregs and is filled with a conductive material to form the via hole 74. Next, conductive foils of the same type as the inner circuit pattern 66 are laminated on the prepreg, and are heated and pressed for contact bonding. The conductive foils on the outermost layers are worked into desired circuit patterns by a known etching process or the like, thus forming outer circuit patterns 72 to obtain a multilayer interconnection board 600.

The multilayer interconnection board 600 according to the first example may have a construction other than that described above, incidentally. For example, adhesive cured layers of the same type as the adhesive cured layers 64 may be formed between the interlayer insulating layers 68 and outer circuit patterns 72. This will accomplish firm bonding between the interlayer insulating layers 68 and outer circuit patterns 72 via their adhesive cured layers, so that the multilayer interconnection board 600 will be highly resistant to peeling not only of the inner circuit patterns 66 but also of the outer circuit patterns 72.

Instead of forming the interlayer insulating layers 68 and outer circuit patterns 72 in order as described above, a multilayer interconnection board having such a construction with adhesive cured layers between the interlayer insulating layers 68 and outer circuit patterns 72 can alternatively be obtained by, for example, laminating adhesive layer-attached conductive foils 100 such as used for fabrication of the circuit board 400, on core boards 80. The multilayer interconnection board 600 may also be produced by laminating printed circuit boards 400 bearing the same or different circuit patterns 36 on the core boards 80.

The multilayer interconnection board 600 may have any desired number of laminated layers, without being limited to the number shown in the drawing. Such a multilayer interconnection board 600 may be produced by either alternately laminating interlayer insulating layers 68 and outer circuit patterns 72 on both sides of a core board 80 to the desired number of layers, or by laminating printed circuit boards 400 to the desired number of layers.

### Second Example

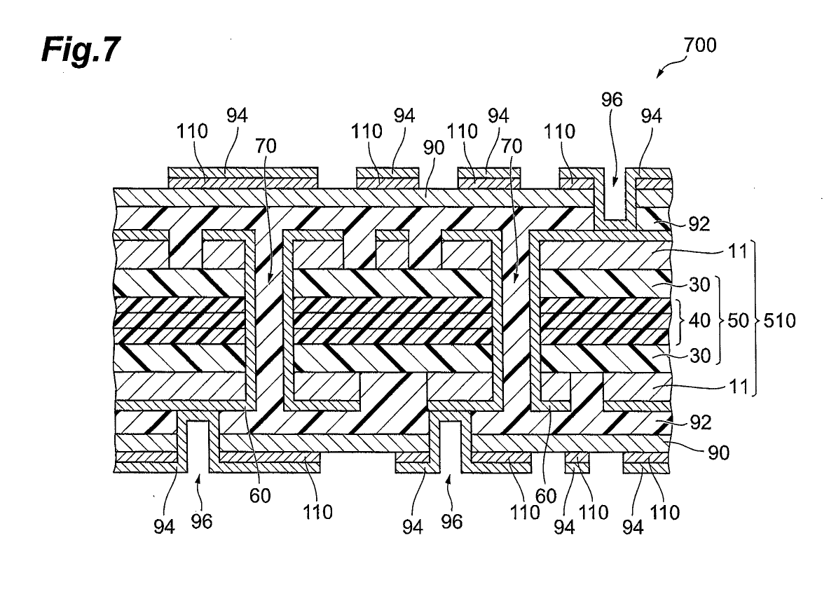

FIG. 7 shows the partial cross-sectional construction of a multilayer interconnection board according to a second example. The multilayer interconnection board 700 shown in FIG. 7 comprises insulating resin layers 92 each composed of a cured prepreg (base), laminated on both sides of a core board 510, adhesive cured layers 90 formed on the sides of the insulating resin layers 92 opposite the core board 510, and outer circuit patterns 110 formed on the outer surfaces of the adhesive cured layers 90. The core board 510 has the same construction as the printed circuit board 500 described above, and the circuit patterns 11 of the core board 510 correspond to the inner circuit patterns 11. In other words, the multilayer interconnection board 700 employs the aforementioned printed circuit board 500 as the core board 510.

The multilayer interconnection board 700 having this construction is preferably produced using the printed circuit board 500. That is, first a printed circuit board 500 is prepared for use as the inner core board 510. One layer or a plurality of layers of prepregs such as used for fabrication of the conductor-clad laminated sheet 300 are stacked on both sides of the inner core board 510. The adhesive layer-attached conductive foils 100 are then further stacked over both outer surfaces of the prepregs, with their adhesive layers 20 in contact therewith.

The obtained laminated body is then hot pressure molded to bond the layers together. This forms insulating resin layers 92 from the prepregs laminated on the inner core board 510, and adhesive cured layers 90 are formed from the adhesive layers 20 of the adhesive layer-attached conductive foil 100. Next, drilling and plated coating are performed in the same manner as for fabrication of the printed circuit board 500, to form through-holes 96 and plated coatings 94. The drilling may be carried out only to the sections laminated on the inner core board 510, or it may be carried out completely through the inner core board 510. The outermost conductive foils (conductive foils 10) and the plated coatings 94 formed thereover are then worked into prescribed circuit shapes by a known process to form outer circuit patterns 110, thus completing the multilayer interconnection board 700. The multilayer interconnection board according to the second example may have a construction other than described above, incidentally. For example, the multilayer interconnection board of the second example may be obtained by alternately laminating a prepreg and a printed circuit board 500 on the surface of a printed circuit board 500 as the core board, and hot pressure molding the obtained laminated body. In this type of multilayer interconnection board, the outermost outer circuit patterns may be obtained by working the conductive foils bonded via the prepregs or by working the conductive foils 10 of the adhesive layer-attached conductive foils 100 laminated on the outermost surfaces, or they may be circuit patterns 11 of the printed circuit boards 500 laminated on the outermost layers.

Preferred embodiments of adhesive layer-attached conductive foils, conductor-clad laminated sheets, printed circuit boards and multilayer interconnection boards according to the invention were described above, but the present invention is not limited only to these embodiments, and various modifications may be implemented such as are within the gist of the invention.

### EXAMPLES

The present invention will now be explained in greater detail through the following examples, with the understanding that these examples are in no way limitative on the invention.

### Synthesis of Polyamideimide

### Synthesis Example 1A

First, in a 1 L separable flask equipped with a Dean-Stark reflux condenser, thermometer and stirrer there were placed 45 mmol of (4,4′-diamino)dicyclohexylmethane (WONDAMINE HM (WHM), trade name of New Japan Chemical Co., Ltd.) as a diamine compound with a saturated alicyclic hydrocarbon group, 5 mmol of a reactive silicone oil (X-22-161-B, trade name of Shin-Etsu Chemical Co., Ltd., amine equivalents: 1500) as a siloxanediamine compound, 105 mmol of trimellitic anhydride (TMA) and 145 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 60 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 1A (solid concentration: 30 wt %). The weight-average molecular weight (Mw) of the NMP solution was measured by gel permeation chromatography to be 50,000.

### Synthesis Example 2A

First, in a 1 L separable flask equipped with a Dean-Stark reflux condenser, thermometer and stirrer there were placed 30 mmol of JEFFAMINE D-2000 (trade name of San Techno Chemical Co., Ltd.) as a diamine compound with a saturated aliphatic hydrocarbon group, 120 mmol of (4,4′-diamino)diphenylmethane (DDM) as an aromatic diamine compound, 315 mmol of trimellitic anhydride (TMA) and 442 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 180 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 2A (solid concentration: 30 wt %). The weight-average molecular weight (Mw) of the NMP solution was measured by gel permeation chromatography to be 74,000.

### Preparation of Adhesive Layer Resin Varnish (Curable Resin Composition)

### Preparation Example 1A

After combining 5.0 g of a cresol-novolac-type epoxy resin (YDCN-500 trade name of Tohto Kasei Co., Ltd.) as component (A), 3.1 g of a novolac-type phenol resin (MEH7500, trade name of Meiwa Plastic Industries, Ltd.) as component (B) and 18 g of the polyamideimide NMP solution obtained in Synthesis Example 1A as component (C), and further adding 0.025 g of 2-ethyl-4-methylimidazole (2E4 MZ, trade name of Shikoku Chemicals Corp.) as a curing accelerator, the mixture was combined with 28 g of N-methyl-2-pyrrolidone and 13 g of methyl ethyl ketone to prepare an adhesive layer resin varnish for Preparation Example 1A (solid concentration: approximately 20 wt %).

The resin composition obtained by curing the resin comprising 2E4 MZ added to YDCN-500 and MEH7500 had a glass transition temperature (Tg) of 190° C. The glass transition temperature (Tg) is the value measured by differential scanning calorimetry (DSC) according to JIS-K7121-1987.

### Preparation Example 2A

After combining 5.0 g of a phenol-novolac-type epoxy resin (N-770, trade name of Dainippon Ink and Chemicals, Inc.) as component (A), 3.9 g of a cresol-novolac-type phenol resin (KA-1163, trade name of Dainippon Ink and Chemicals, Inc.) as component (B), 55 g of the polyamideimide NMP solution obtained in Synthesis Example 2A as component (C) and 8.5 g of carboxylic acid-modified acrylonitrile-butadiene rubber particles (XER-91 SE-15, trade name of JSR Corp., solid concentration: 15 wt %) as component (D), and further adding 0.025 g of 2-ethyl-4-methylimidazole (2E4 MZ, trade name of Shikoku Chemicals Corp.) as a curing accelerator, the mixture was combined with 39 g of N-methyl-2-pyrrolidone and 20 g of methyl ethyl ketone to prepare an adhesive layer resin varnish for Preparation Example 2A (solid concentration: approximately 20 wt %).

The resin composition obtained by curing the resin comprising 2E4 MZ added to N-770 and KA-1163 had a glass transition temperature (Tg) of 190° C.

### Preparation Example 3A

After combining 5.0 g of a novolac-type epoxy resin (NC-3000H, trade name of Nippon Kayaku Co., Ltd.) with a biphenyl structure as component (A), 2.0 g of a bisphenol A-novolac resin (YLH129, trade name of Japan Epoxy Resins Co., Ltd.) as component (B), 38 g of the polyamideimide NMP solution obtained in Synthesis Example 1A as component (C) and 0.8 g of a carboxylic acid-modified polyvinylacetal resin (KS-23Z, trade name of Sekisui Chemical Industries, Ltd.) as component (D), and further adding 0.025 g of 2-ethyl-4-methylimidazole (2E4 MZ, trade name of Shikoku Chemicals Corp.) as a curing accelerator, the mixture was combined with 35 g of N-methyl-2-pyrrolidone and 13 g of methyl ethyl ketone to prepare an adhesive layer resin varnish for Preparation Example 3A (solid concentration: approximately 20 wt %).

The resin composition obtained by curing the resin comprising 2E4 MZ added to NC-3000H and YLH129 had a glass transition temperature (Tg) of 170° C.

### Preparation Example 4A

After combining 5.0 g of a bisphenol A-type epoxy resin (DER-331L, trade name of The Dow Chemical Company), 3.2 g of a cresol-novolac-type phenol resin (KA-1163, trade name of Dainippon Ink and Chemicals, Inc.) and 50 g of the polyamideimide NMP solution obtained in Synthesis Example 1A, and further adding 0.025 g of 2-ethyl-4-methylimidazole (2E4 MZ, trade name of Shikoku Chemicals Corp.) as a curing accelerator, the mixture was combined with 46 g of N-methyl-2-pyrrolidone and 15 g of methyl ethyl ketone to prepare an adhesive layer resin varnish for Preparation Example 4A (solid concentration: approximately 20 wt %).

The resin composition obtained by curing the resin comprising 2E4 MZ added to DER-331L and KA1163 had a glass transition temperature (Tg) of 135° C.

### Comparative Preparation Example 1A

With 50 g of the polyamideimide NMP solution obtained in Synthesis Example 1A there was combined 50 g of N-methyl-2-pyrrolidone, to prepare an adhesive layer resin varnish for Comparative Preparation Example 1A (solid concentration: 15 wt %).

### Comparative Preparation Example 2A)

After combining 8.8 g of a cresol-novolac-type epoxy resin (YDCN-500 trade name of Tohto Kasei Co., Ltd.) with 50 g of the polyamideimide NMP solution obtained in Synthesis Example 2A, and further adding 0.088 g of 2-ethyl-4-methylimidazole (2E4 MZ, trade name of Shikoku Chemicals Corp.) as a curing accelerator, the mixture was combined with 101 g of N-methyl-2-pyrrolidone and 34 g of methyl ethyl ketone to prepare an adhesive layer resin varnish for Comparative Preparation Example 2A (solid concentration: approximately 15 wt %).

### Fabrication of Insulating Resin Layer Prepreg

### Fabrication Example 1)

First, 400 g of toluene and 120 g of a polyphenylene ether resin (modified PPO NORYL PKN4752, trade name of Japan GE Plastics) were placed in a 2 L separable flask equipped with a condenser tube, thermometer and stirrer, and the mixture was stirred to dissolution while heating the flask to 90° C.

Next, 80 g of triallyl isocyanurate (TAIC, trade name of Nippon Kasei Chemical Co., Ltd.) was added to the flask while stirring, and upon confirming dissolution or uniform dispersion, the mixture was cooled to room temperature. After then adding 2.0 g of α,α′-bis(t-butylperoxy)diisopropylbenzene (PERBUTYL P, trade name of NOF Corp.) as a radical polymerization initiator, 70 g of toluene was further added to obtain an insulating resin layer varnish with a solid concentration of approximately 30 wt %.

The obtained insulating resin layer varnish was impregnated into 0.1 mm-thick glass fibers (E glass, product of Nitto Boseki Co., Ltd.), and then heated and dried at 120° C. for 5 minutes to obtain an insulating resin layer prepreg for Fabrication Example 1, having a resin content of 50 wt %.

### Fabrication Example 2

First, 400 g of toluene and 120 g of a polyphenylene ether resin (modified PPO NORYL PKN4752, trade name of Japan GE Plastics) were placed in a 2 L separable flask equipped with a condenser tube, thermometer and stirrer, and the mixture was stirred to dissolution while heating the flask to 90° C.

Next, 80 g of 1,2-polybutadiene (B-1000, trade name of Nippon Soda Co., Ltd.) and 10 g of divinylbenzene (DVB) as a crosslinking aid were added to the flask while stirring, and upon confirming dissolution or uniform dispersion, the mixture was cooled to room temperature.

After then adding 2.0 g of α,α′-bis(t-butylperoxy)diisopropylbenzene (PERBUTYL P, trade name of NOF Corp.) as a radical polymerization initiator, 70 g of toluene was further added to obtain an insulating resin layer varnish with a solid concentration of approximately 30 wt %.

The obtained insulating resin layer varnish was impregnated into 0.1 mm-thick glass fibers (E glass, product of Nitto Boseki Co., Ltd.), and then heated and dried at 120° C. for 5 minutes to obtain an insulating resin layer prepreg for Fabrication Example 2, having a resin content of 50 wt %.

### Fabrication Example 3

First, 5000 mL of tetrahydrofuran (THF) and 100 g of a polyphenylene ether resin (modified NORYL PPO646-111, trade name of Japan GE Plastics) were placed in a 10 L separable flask equipped with a condenser tube, thermometer and stirrer, and the mixture was stirred to dissolution while heating the flask to 60° C. After returning the contents to room temperature, 540 mL of n-butyllithium (1.55 mol/L, hexane solution) was added under a nitrogen stream and stirring was continued for 1 hour. After further adding 100 g of allyl bromide and stirring for 30 minutes, a suitable amount of methanol was combined therewith and the precipitated polymer was separated out to obtain an allylated polyphenylene ether.

Next, 400 g of toluene and 100 g of the allylated polyphenylene ether were placed in a 2 L separable flask equipped with a condenser tube, thermometer and stirrer, and the mixture was stirred to dissolution while heating the flask to 90° C.

To the flask there was then added 100 g of triallyl isocyanurate (TAIC, trade name of Nippon Kasei Chemical Co., Ltd.) while stirring, and upon confirming dissolution or uniform dispersion, the mixture was cooled to room temperature.

After then adding 2.5 g of α,α′-bis(t-butylperoxy)diisopropylbenzene (PERBUTYL P, trade name of NOF Corp.) as a radical polymerization initiator, 70 g of toluene was further added to obtain an insulating resin layer varnish with a solid concentration of approximately 30 wt %.

The obtained insulating resin layer varnish was impregnated into 0.1 mm-thick glass fibers (E glass, product of Nitto Boseki Co., Ltd.), and then heated and dried at 120° C. for 5 minutes to obtain an insulating resin layer prepreg for Fabrication Example 3, having a resin content of 50 wt %.

### Examples 1A-4A and Comparative Examples 1A-2A

### Fabrication of Adhesive Layer-Attached Conductive Foils

Each of the adhesive layer resin varnishes obtained in Preparation Examples 1A-4A and Comparative Preparation Examples 1A and 2A was coated by natural casting onto the M-surface [surface roughness (Rz): 0.8 μm) of a 18 μm-thick electrolytic copper foil (F0-WS-18, low-profile copper foil by Furukawa Electric Co., Ltd.), and then dried at 170° C. for 5 minutes to fabricate adhesive layer-attached conductive foils for Examples 1A, 2A, 3A and 4A and for Comparative Examples 1A and 2A. The post-drying thickness of each adhesive layer was 2 μm. The use of the adhesive layer resin varnishes of Preparation Examples 1A, 2A, 3A and 4A corresponds to Examples 1A, 2A, 3A and 4A, and the use of the adhesive layer resin varnishes of Comparative Preparation Examples 1A and 2A corresponds to Comparative Examples 1A and 2A, respectively.

### (Fabrication of Double-Sided Copper Clad Laminates and Multilayer Boards)

The adhesive layer-attached conductive foils of Examples 1A-4A and Comparative Examples 1A and 2A and the insulating resin layer prepregs of Fabrication Examples 1-3 were used in prescribed combinations to produce double-sided copper clad laminates and multilayer boards, corresponding to using the adhesive layer-attached prepregs of the respective examples and comparative examples, by the methods described below. The combinations of the adhesive layer-attached prepregs and insulating resin layer prepregs of each of the examples and comparative examples were as shown in Table 1 below.

### (Fabrication of Double-Sided Copper Clad Laminates)

After adhering adhesive layer-attached conductive foils onto both sides of a base comprising four laminated insulating resin layer prepregs, with their adhesive layers in contact therewith, the laminate was hot pressure molded under pressing conditions with a temperature of 200° C., a pressure of 3.0 MPa and a time of 70 minutes, to fabricate double-sided copper clad laminates (0.55 mm thickness) comprising each type of adhesive layer-attached conductive foil.

### (Fabrication of Multilayer Boards)

First, the same types of double-sided copper clad laminates as above were fabricated. Next, the copper foil sections of each double-sided copper clad laminate were completely removed by etching, and then the same prepregs as the insulating resin layer prepregs used for fabrication of the copper clad laminates were situated on either side of the copper foil-removed double-sided copper clad laminate, and 18 μm-thick electrolytic copper foils [GTS-18, trade name of ordinary copper foil by Furukawa Electric Co., Ltd., M-surface roughness (Rz): 8 μm] without adhesive layers were adhered to the outside thereof with the M-surfaces in contact. The laminate was then hot pressure molded under pressing conditions with a temperature of 200° C., a pressure of 3.0 MPa and a time of 70 minutes, to fabricate a multilayer board.

### Comparative Examples 3A and 4A

For comparison, 18 μm-thick electrolytic copper foils (F0-WS-18, trade name of Furukawa Electric Co., Ltd.) without adhesive layers or 18 μm-thick electrolytic copper foils [GTS-18, trade name of ordinary copper foil by Furukawa Electric Co., Ltd., M-surface roughness (Rz): 8 μm] without adhesive layers were adhered to both sides of a base comprising four laminated insulating resin layer prepregs of Fabrication Example 1 or 2, with the M-surfaces in contact therewith. The laminate was then hot pressure molded under pressing conditions of 200° C., 3.0 MPa, 70 minutes. Thus, two different double-sided copper clad laminates (0.55 mm thickness) provided with different electrolytic copper foils on their surfaces were fabricated. The double-sided copper clad laminate with the former electrolytic copper foil was designated as Comparative Example 3A, and the one with the latter electrolytic copper foil was designated as Comparative Example 4A. The double-sided copper clad laminates were used to fabricate multilayer boards in the same manner as above.

### [Evaluation of Physical Properties]

### (Measurement of Copper Foil Peel Strengths of Copper Clad Laminates)

First, the double-sided copper clad laminates of Examples 1A-4A and Comparative Examples 1A-4A were used for measurement of the copper foil peel strengths of each of the double-sided copper clad laminates by the following method. Specifically, first the copper foil of each double-sided copper clad laminate was subjected to etching to remove the undesired copper foil sections in order to form a circuit shape with a line width of 5 mm, thus producing a laminated sheet sample with a 2.5 cm×10 cm two-dimensional configuration. The prepared sample was then held for 5 hours under both ordinary conditions and in a pressure cooker test (PCT) apparatus (conditions: 121° C., 2.2 atmospheres, 100% RH). The copper foil peel strength (units: kN/m) of the double-sided copper clad laminate after 5 hours was measured under the following conditions. The results are shown in Table 1.
Test method: 90° tensile test
Pull rate: 50 mm/min
Measuring apparatus: AG-10° C. Autograph by Shimadzu Corp.

The copper foil peel strength indicated as “−” in the table means that the copper foil peel strength could not be measured because the copper foil had already peeled after being held in the PCT.

(Evaluation of Soldering Heat Resistance of Double-Sided Copper Clad Laminates and Multilayer Boards)

The soldering heat resistance of the double-sided copper clad laminates and multilayer boards of Examples 1A-4A and Comparative Examples 1A-4A were evaluated according to the following method. Specifically, first the double-sided copper clad laminate or multilayer board was cut to a size of 50 mm square. Next, the copper foil on one side of the double-sided copper clad laminate was etched to the prescribed shape, or the external copper foil on the multilayer board was etched to complete removal, to obtain an evaluation sample. A plurality of evaluation samples were prepared for each of the examples and comparative examples, to be used in the tests described hereunder.

The evaluation samples corresponding to the examples and comparative examples were then treated by being held under ordinary conditions or in a pressure cooker test (PCT) apparatus (conditions: 121° C., 2.2 atmospheres) for a prescribed period of time (1, 2, 3, 4 or 5 hours). Each treated evaluation sample was then immersed for 20 seconds in molten solder at 260° C. The appearances of three evaluation samples each of the double-sided copper clad laminates and multilayer boards corresponding to the examples and comparative examples were visually examined. The results are shown in Table 1.

The numerical values in the tables represent the numbers of samples among the three tested evaluation samples that exhibited no swelling or measling between the insulating layer and copper foil (conductive layer). A larger number represents more excellent heat resistance of the corresponding evaluation sample.

(Evaluation of Transmission Loss of Double-Sided Copper Clad Laminates)

The transmission loss (units: dB/m) of each of the double-sided copper clad laminates of Examples 1A-4A and Comparative Examples 1A-4A was measured by the triplate line resonator method using a vector network analyzer. The measuring conditions were a line width of 0.6 mm, an insulating layer distance of 1.04 mm between the upper and lower ground conductors, a line length of 200 mm, a characteristic impedance of 50Ω, a frequency of 3 GHz and a measuring temperature of 25° C. The results are shown in Table 1.

TABLE 1

| | | | Example | Example | Example | Example | Comp. | Comp. | Comp. | Comp. |
|---|---|---|---|---|---|---|---|---|---|---|
| | | | 1A | 2A | 3A | 4A | Ex. 1A | Ex. 2A | Ex. 3A | Ex. 4A |
| Adhesive layer-attached | | | Example | Example | Example | Example | Comp. | Comp. | — | — |
| conductive foil | | | 1A | 2A | 3A | 4A | Ex. 1A | Ex. 2A | | |
| Insulating resin layer | | | Fabrication | Fabrication | Fabrication | Fabrication | Fabrication | Fabrication | Fabrication | Fabrication |
| prepreg | | | Ex. 1 | Ex. 2 | Ex. 3 | Ex. 3 | Ex. 1 | Ex. 2 | Ex. 1 | Ex. 2 |
| Peel strength | | Original | 0.82 | 1.08 | 0.95 | 0.88 | 1.32 | 1.21 | 0.20 | 0.90 |
| (kN/m) | | state | | | | | | | | |
| | | After | 0.71 | 0.82 | 0.74 | 0.66 | 0.80 | 0.71 | — | 0.33 |
| | | PCT | | | | | | | | |
| Soldering | Copper- | Original | 3 | 3 | 3 | 3 | 3 | 3 | 2 | 3 |
| heat | clad | state | | | | | | | | |
| resistance | board | 1 hr | 3 | 3 | 3 | 3 | 3 | 3 | 0 | 3 |
| (original | | 2 hrs | 3 | 3 | 3 | 3 | 3 | 3 | 0 | 3 |
| state/after | | 3 hrs | 3 | 3 | 3 | 3 | 3 | 3 | 0 | 3 |
| PCT) | | 4 hrs | 3 | 3 | 3 | 2 | 2 | 3 | 0 | 3 |
| | | 5 hrs | 3 | 3 | 3 | 0 | 0 | 2 | 0 | 3 |
| | Multilayer | Original | 3 | 3 | 3 | 3 | 3 | 3 | 2 | 3 |
| | board | state | | | | | | | | |
| | | 1 hr | 3 | 3 | 3 | 3 | 1 | 3 | 0 | 3 |
| | | 2 hrs | 3 | 3 | 3 | 3 | 0 | 1 | 0 | 3 |
| | | 3 hrs | 3 | 3 | 3 | 2 | 0 | 0 | 0 | 3 |
| | | 4 hrs | 3 | 3 | 3 | 1 | 0 | 0 | 0 | 3 |
| | | 5 hrs | 3 | 3 | 2 | 0 | 0 | 0 | 0 | 3 |

| | | | | | | | | |
|---|---|---|---|---|---|---|---|---|
| Transmission loss (dB/m) | 4.60 | 4.08 | 4.75 | 4.70 | 4.63 | 4.13 | 4.56 | 5.63 |

Table 1 clearly shows that using the adhesive layer-attached conductive foils of Examples 1A-4A yielded double-sided copper-clad laminates and multilayer boards with excellent copper foil peel strength and soldering heat resistance, as well as the ability to maintain sufficiently low transmission loss. On the other hand, Comparative Examples 1A-4A had notable reduction in copper foil peel strength after PCT, while the soldering heat resistance was insufficient and the transmission loss was inconveniently high.

### Synthesis of Polyamideimide

### Synthesis Example 1B

First, in a 1 L separable flask equipped with a Dean-Stark reflux condenser, thermometer and stirrer there were placed 45 mmol of (4,4′-diamino)dicyclohexylmethane (WONDAMINE HM (WHM), trade name of New Japan Chemical Co., Ltd.) as a diamine compound with a saturated alicyclic hydrocarbon group, 5 mmol of a reactive silicone oil (X-22-161-B, trade name of Shin-Etsu Chemical Co., Ltd., amine equivalents: 1500) as a siloxanediamine compound, 105 mmol of trimellitic anhydride (TMA) and 145 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 60 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 1B (solid concentration: 30 wt %). The weight-average molecular weight (Mw) of the NMP solution was measured by gel permeation chromatography to be 53,000.

### Synthesis Example 2B

First, in a 1 L separable flask equipped with a Dean-Stark reflux condenser, thermometer and stirrer there were placed 30 mmol of JEFFAMINE D-2000 (trade name of San Techno Chemical Co., Ltd.) as a diamine compound with a saturated aliphatic hydrocarbon group, 120 mmol of (4,4′-diamino)diphenylmethane (DDM) as an aromatic diamine compound, 315 mmol of trimellitic anhydride (TMA) and 442 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 180 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 2B (solid concentration: 30 wt %). The weight-average molecular weight (Mw) of the NMP solution was measured by gel permeation chromatography to be 74,000.

### Synthesis Example 3B

An NMP solution of a polyamideimide was obtained in the same manner as Synthesis Example 1B, except that the amount of MDI was changed to 50 mmol. The weight-average molecular weight (Mw) of the NMP solution was measured by gel permeation chromatography to be 23,000.

### Synthesis Example 4B

An NMP solution of a polyamideimide was obtained in the same manner as Synthesis Example 2B, except that the amount of MDI was changed to 190 mmol and the reaction time was changed to 3 hours. The weight-average molecular weight (Mw) of the NMP solution was measured by gel permeation chromatography to be 270,000.

### Preparation of Adhesive Layer Resin Varnish (Curable Resin Composition)

### Preparation Example 1B

After adding 3.1 g of a novolac-type phenol resin (MEH7500, trade name of Meiwa Plastic Industries, Ltd.) as component (B) and 18 g of the polyamideimide NMP solution obtained in Synthesis Example 1B as component (C) to 5.0 g of a cresol-novolac-type epoxy resin (YDCN-500 trade name of Tohto Kasei Co., Ltd.) as component (A), and further adding 0.025 g of 2-ethyl-4-methylimidazole (2E4 MZ, trade name of Shikoku Chemicals Corp.) as a curing accelerator, the mixture was combined with 28 g of N-methyl-2-pyrrolidone and 13 g of methyl ethyl ketone to prepare an adhesive layer resin varnish for Preparation Example 1B (solid concentration: approximately 20 wt %).

The resin composition obtained by curing the resin comprising 2E4 MZ added to YDCN-500 and MEH7500 had a glass transition temperature (Tg) of 190° C.

### Preparation Example 2B

After adding 2.0 g of a bisphenol A-novolac resin (YLH129, trade name of Japan Epoxy Resins Co., Ltd.) as component (B), 38 g of the polyamideimide NMP solution obtained in Synthesis Example 2B as component (C) and 0.8 g of a carboxylic acid-modified polyvinylacetal resin (KS-23Z, trade name of Sekisui Chemical Industries, Ltd.) as component (D) to 5.0 g of a novolac-type epoxy resin (NC-3000H, trade name of Nippon Kayaku Co., Ltd.) with a biphenyl structure as component (A), and further adding 0.025 g of 2-ethyl-4-methylimidazole (2E4 MZ, trade name of Shikoku Chemicals Corp.) as a curing accelerator, the mixture was combined with 35 g of N-methyl-2-pyrrolidone and 13 g of methyl ethyl ketone to prepare an adhesive layer resin varnish for Preparation Example 2B (solid concentration: approximately 20 wt %).

The resin composition obtained by curing the resin comprising 2E4 MZ added to NC-3000H and YLH129 had a glass transition temperature (Tg) of 170° C.

### Preparation Example 3B

After adding 3.9 g of a cresol-novolac-type phenol resin (KA-1163, trade name of Dainippon Ink and Chemicals, Inc.) as component (B), 55 g of the polyamideimide NMP solution obtained in Synthesis Example 2B as component (C) and 8.5 g of carboxylic acid-modified acrylonitrile-butadiene rubber particles (XER-91SE-15, trade name of JSR Corp., solid concentration: 15 wt %) as component (D) to 5.0 g of a phenol-novolac-type epoxy resin (N-770, trade name of Dainippon Ink and Chemicals, Inc.) as component (A), and further adding 0.025 g of 2-ethyl-4-methylimidazole (2E4 MZ, trade name of Shikoku Chemicals Corp.) as a curing accelerator, the mixture was combined with 39 g of N-methyl-2-pyrrolidone and 20 g of methyl ethyl ketone to prepare an adhesive layer resin varnish for Preparation Example 3B (solid concentration: approximately 20 wt %).

The resin composition obtained by curing the resin comprising 2E4 MZ added to N-770 and KA-1163 had a glass transition temperature (Tg) of 190° C.

### Preparation Example 4B

After adding 3.2 g of a cresol-novolac-type phenol resin (KA-1163, trade name of Dainippon Ink and Chemicals, Inc.) and 50 g of the polyamideimide NMP solution obtained in Synthesis Example 2B to 5.0 g of a bisphenol A-type epoxy resin (DER-331L, trade name of The Dow Chemical Company), and further adding 0.025 g of 2-ethyl-4-methylimidazole (2E4 MZ, trade name of Shikoku Chemicals Corp.) as a curing accelerator, the mixture was combined with 46 g of N-methyl-2-pyrrolidone and 15 g of methyl ethyl ketone to prepare an adhesive layer resin varnish for Preparation Example 4B (solid concentration: approximately 20 wt %).

The resin composition obtained by curing the resin comprising 2E4 MZ added to DER-331L and KA1163 had a glass transition temperature (Tg) of 135° C.

### Preparation Example 5B

An adhesive layer resin varnish was prepared in the same manner as Preparation Example 2B, except that the solution obtained in Synthesis Example 3B was used as the polyamideimide NMP solution instead of the solution obtained in Synthesis Example 2B.

### Preparation Example 6B

An adhesive layer resin varnish was prepared in the same manner as Preparation Example 2B, except that the solution obtained in Synthesis Example 4B was used as the polyamideimide NMP solution instead of the solution obtained in Synthesis Example 2B.

### [Fabrication of Insulating Resin Layer Prepregs]

Insulating resin layer prepregs for Fabrication Examples 1-3 were produced in the same manner as described above.

### Examples 1B-6B

### Fabrication of Adhesive Layer-Attached Conductive Foils

Each of the adhesive layer resin varnishes obtained in Preparation Examples 1B-6B was coated by natural casting onto the M-surface [surface roughness (Rz)=0.8 μm) of a 12 μm-thick electrolytic copper foil (F0-WS-12, low-profile copper foil by Furukawa Electric Co., Ltd.), and then dried at 150° C. for 5 minutes to fabricate adhesive layer-attached conductive foils for Examples 1B-6B. The post-drying thickness of each adhesive layer was 3 μm. Use of the varnishes of Preparation Examples 1B, 2B, 3B, 4B, 5B and 6B corresponds to Examples 1B, 2B, 3B, 4B, 5B and 6B, respectively.

### (Fabrication of Double-Sided Copper Clad Laminates)

After adhering each of the adhesive layer-attached conductive foils of Examples 1B-6B onto both sides of a base comprising four laminated insulating resin layer prepregs selected from among Fabrication Examples 1-3 described above, with their adhesive layers in contact therewith, each laminate was hot pressure molded under pressing conditions of 200° C., 3.0 MPa, 70 minutes, to fabricate double-sided copper clad laminates (0.55 mm thickness) comprising the adhesive layer-attached conductive foils of Examples 1B-6B. The combinations of the adhesive layer-attached conductive foils and insulating layer prepregs of each of the examples and comparative examples were as shown in Table 2 below.

(Fabrication of Multilayer Boards)

First, double-sided copper clad laminates were formed using each of the adhesive layer-attached conductive foils of Examples 1B-6B in the same manner as above, and the copper foil sections were completely removed by etching. Next, the same prepregs as the insulating resin layer prepregs used for fabrication of the copper clad laminates were situated on either side of each of the copper foil-removed double-sided copper clad laminates, and then 12 μm-thick electrolytic copper foils [GTS-12, trade name of ordinary copper foil by Furukawa Electric Co., Ltd., M-surface roughness (Rz)=8 μm] without adhesive layers were adhered to the outside thereof with the M-surfaces in contact therewith, and hot pressure molding was performed under pressing conditions of 200° C., 3.0 MPa, 70 minutes to fabricate multilayer boards. The combinations of the adhesive layer-attached conductive foils of Examples 1B-6B with the insulating resin layer prepregs of Fabrication Examples 1-3 were as shown in Table 2.

### Comparative Examples 1B-2B

For comparison, 12 μm-thick electrolytic copper foils (F0-WS-12, trade name of Furukawa Electric Co., Ltd.) without adhesive layers or 12 μm-thick electrolytic copper foils [GTS-12, trade name of ordinary copper foil by Furukawa Electric Co., Ltd., M-surface roughness (Rz): 8 μm] without adhesive layers were adhered to both sides of a base comprising four laminated insulating resin layer prepregs of Fabrication Example 1, with the M-surfaces in contact therewith, and then hot pressure molding was performed under pressing conditions of 200° C., 3.0 MPa, 70 minutes to fabricate double-sided copper clad laminates (0.55 mm thickness). The double-sided copper clad laminates were used to fabricate multilayer boards in the same manner as above. Use of the former electrolytic copper foil corresponds to Comparative Example 1B, and use of the latter electrolytic copper foil corresponds to Comparative Example 2B.

### [Evaluation of Physical Properties]

(Measurement of Copper Foil Peel Strengths of Copper Clad Laminates)

The double-sided copper clad laminates obtained in Examples 1B-6B and Comparative Examples 1B-2B were used to measure the copper foil peel strengths (units: kN/m) by the same method as described above. The results are shown in Table 2.

The copper foil peel strength indicated as “−” in the table means that the copper foil peel strength could not be measured because the copper foil had already peeled after being held in the PCT.

(Evaluation of Soldering Heat Resistance of Copper Clad Laminates And Multilayer Boards)

The double-sided copper clad laminates and multilayer boards obtained in Examples 1B-6B and Comparative Examples 1B and 2B were used for evaluation of their soldering heat resistance by the same method as described above. The results are shown in Table 2.

(Evaluation of Transmission Loss of Double-Sided Copper Clad Laminates)

The transmission loss (units: dB/m) of each of the double-sided copper clad laminates obtained in Examples 1B-6B and Comparative Examples 1B and 2B was measured in the same manner as described above. The results are shown in Table 2.

TABLE 2

| | | | Example | Example | Example | Example | Example | Example | Comp. | Comp. |
|---|---|---|---|---|---|---|---|---|---|---|
| | | | 1B | 2B | 3B | 4B | 5B | 6B | Ex. 1B | Ex. 2B |
| Adhesive layer-attached | | | Example | Example | Example | Example | Example | Example | — | — |
| conductive foil | | | 1B | 2B | 3B | 4B | 5B | 6B | | |
| Insulating resin layer | | | Fabrication | Fabrication | Fabrication | Fabrication | Fabrication | Fabrication | Fabrication | Fabrication |
| prepreg | | | Ex. 1 | Ex. 3 | Ex. 2 | Ex. 2 | Ex. 1 | Ex. 3 | Ex. 1 | Ex. 1 |
| Peel strength | | Original | 0.72 | 0.77 | 0.82 | 0.78 | 0.45 | 0.51 | 0.08 | 0.72 |
| (kN/m) | | state | | | | | | | | |
| | | After PCT | 0.68 | 0.67 | 0.71 | 0.68 | 0.33 | 0.44 | — | 0.22 |
| Soldering | Copper- | Original | 3 | 3 | 3 | 3 | 3 | 3 | 2 | 3 |
| heat | clad | state | | | | | | | | |
| resistance | board | 1 hr | 3 | 3 | 3 | 3 | 3 | 3 | 0 | 3 |
| (original | | 2 hrs | 3 | 3 | 3 | 3 | 3 | 3 | 0 | 3 |
| state/after | | 3 hrs | 3 | 3 | 3 | 2 | 3 | 3 | 0 | 3 |
| PCT) | | 4 hrs | 3 | 3 | 3 | 0 | 2 | 3 | 0 | 3 |
| | | 5 hrs | 3 | 3 | 3 | 0 | 0 | 2 | 0 | 3 |
| | Multilayer | Original | 3 | 3 | 3 | 3 | 3 | 3 | 2 | 3 |
| | board | state | | | | | | | | |
| | | 1 hr | 3 | 3 | 3 | 2 | 1 | 3 | 0 | 3 |
| | | 2 hrs | 3 | 3 | 3 | 0 | 0 | 2 | 0 | 3 |
| | | 3 hrs | 3 | 3 | 3 | 0 | 0 | 0 | 0 | 3 |
| | | 4 hrs | 3 | 3 | 3 | 0 | 0 | 0 | 0 | 3 |
| | | 5 hrs | 3 | 2 | 3 | 0 | 0 | 0 | 0 | 3 |

| | | | | | | | | |
|---|---|---|---|---|---|---|---|---|
| Transmission loss (dB/m) | 4.65 | 4.80 | 4.12 | 4.11 | 4.66 | 4.82 | 4.66 | 5.33 |

Table 2 clearly shows that more excellent copper foil peel strength and soldering heat resistance were obtained with Examples 1B-6B than with Comparative Examples 1B and 2B, while sufficient low transmission loss was also possible. Also, it was confirmed that even higher copper foil peel strength and soldering heat resistance was obtained with Examples 1B-4B compared to Examples 5B and 6B.

### Synthesis of Polyamideimide

### Synthesis Example 1C

First, in a 1 L separable flask equipped with a Dean-Stark reflux condenser, thermometer and stirrer there were placed 45 mmol of (4,4′-diamino)dicyclohexylmethane (WONDAMINE HM (WHM), trade name of New Japan Chemical Co., Ltd.) as a diamine compound with a saturated alicyclic hydrocarbon group, 5 mmol of a reactive silicone oil (X-22-161-B, trade name of Shin-Etsu Chemical Co., Ltd., amine equivalents: 1500) as a siloxanediamine compound, 105 mmol of trimellitic anhydride (TMA) and 85 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 60 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 1C (solid concentration: 30 wt %). The weight-average molecular weight (Mw) of the NMP solution was measured by gel permeation chromatography to be 34,000.

### Synthesis Example 2C

First, in a 1 L separable flask equipped with a Dean-Stark reflux condenser, thermometer and stirrer there were placed 10 mmol of JEFFAMINE D-2000 (trade name of San Techno Chemical Co., Ltd.) as a diamine compound with a saturated aliphatic hydrocarbon group, 40 mmol of (4,4′-diamino)dicyclohexylmethane (WONDAMINE HM (WHM), trade name of New Japan Chemical Co., Ltd.) as a diamine compound with a saturated alicyclic hydrocarbon group, 105 mmol of trimellitic anhydride (TMA) and 150 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 180 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 2C (solid concentration: 30 wt %). The weight-average molecular weight (Mw) of the NMP solution was measured by gel permeation chromatography to be 84,000.

### Synthesis Example 3C

First, in a 1 L separable flask equipped with a Dean-Stark reflux condenser, thermometer and stirrer there were placed 30 mmol of JEFFAMINE D-2000 (trade name of San Techno Chemical Co., Ltd.) as a diamine compound with a saturated aliphatic hydrocarbon group, 120 mmol of (4,4′-diamino)diphenylmethane (DDM) as an aromatic diamine compound, 315 mmol of trimellitic anhydride (TMA) and 100 g of N-methyl-2-pyrrolidone (NMP) as an aprotic polar solvent, and the temperature in the flask was set to 80° C. prior to stirring for 30 minutes.

Upon completion of stirring, 100 mL of toluene was further added as an aromatic hydrocarbon capable of forming an azeotropic mixture with water, and then the temperature in the flask was raised to 160° C. for approximately 2 hours of reflux. After a stoichiometric amount of water had accumulated in the water measuring receptacle and no further run-off of water occurred, the temperature in the flask was raised to 190° C. to remove the toluene in the reaction mixture, while removing the water in the water measuring receptacle.

After returning the solution in the flask to room temperature, 180 mmol of 4,4′-diphenylmethane diisocyanate (MDI) was added as a diisocyanate, and the temperature in the flask was raised to 190° C. for 2 hours of reaction, followed by dilution with NMP to obtain an NMP solution of a polyamideimide for Synthesis Example 3C (solid concentration: 30 wt %). The weight-average molecular weight (Mw) of the NMP solution was measured by gel permeation chromatography to be 74,000.

### Preparation of Adhesive Layer Resin Varnish (Curable Resin Composition)

### Preparation Example 1C

To 5.0 g of a cresol-novolac-type epoxy resin (YDCN-500, trade name of Tohto Kasei Co., Ltd.) as component (A) there were added 3.1 g of a novolac-type phenol resin (MEH7500, trade name of Meiwa Plastic Industries, Ltd.) as component (B) and 18 g of the polyamideimide NMP solution obtained in Synthesis Example 1C, as component (C). After adding 0.025 g of 2-ethyl-4-methylimidazole (2E4 MZ, trade name of Shikoku Chemicals Corp.) as a curing accelerator, the mixture was combined with 28 g of N-methyl-2-pyrrolidone and 13 g of methyl ethyl ketone to prepare an adhesive layer resin varnish for Preparation Example 1C (solid concentration: approximately 20 wt %).

The resin composition obtained by curing the resin comprising 2E4 MZ added to YDCN-500 and MEH7500 had a glass transition temperature (Tg) of 190° C.

### Preparation Example 2C

To 5.0 g of a phenol-novolac-type epoxy resin (N-770, trade name of Dainippon Ink and Chemicals, Inc.) as component (A) there were added 3.9 g of a cresol-novolac-type phenol resin (KA-1165, trade name of Dainippon Ink and Chemicals, Inc.) as component (B) and 55 g of the polyamideimide NMP solution obtained in Synthesis Example 2C, as component (C). After adding 0.025 g of 2-ethyl-4-methylimidazole (2E4 MZ, trade name of Shikoku Chemicals Corp.) as a curing accelerator, the mixture was combined with 39 g of N-methyl-2-pyrrolidone and 20 g of methyl ethyl ketone to prepare an adhesive layer resin varnish for Preparation Example 2C (solid concentration: approximately 20 wt %).

The resin composition obtained by curing the resin comprising 2E4 MZ added to N-770 and KA-1165 had a glass transition temperature (Tg) of 190° C.

### Preparation Example 3C

To 5.0 g of a novolac-type epoxy resin with a biphenyl structure (NC-3000H, trade name of Nippon Kayaku Co., Ltd.) as component (A) there were added 2.0 g of a bisphenol A-novolac resin (YLH129, trade name of Japan Epoxy Resins Co., Ltd.) as component (B) and 38 g of the polyamideimide NMP solution obtained in Synthesis Example 3C, as component (C). After adding 0.025 g of 2-ethyl-4-methylimidazole (2E4 MZ, trade name of Shikoku Chemicals Corp.) as a curing accelerator, the mixture was combined with 35 g of N-methyl-2-pyrrolidone and 13 g of methyl ethyl ketone to prepare an adhesive layer resin varnish for Preparation Example 3C (solid concentration: approximately 20 wt %).

The resin composition obtained by curing the resin comprising 2E4 MZ added to NC-3000H and YLH-129 had a glass transition temperature (Tg) of 170° C.

### Preparation Example 4C

To 5.0 g of a bisphenol A-type epoxy resin (DER-331L, trade name of The Dow Chemical Company) as component (A) there were added 3.2 g of a cresol-novolac-type phenol resin (KA-1163, trade name of Dainippon Ink and Chemicals, Inc.) as component (B) and 50 g of the polyamideimide NMP solution obtained in Synthesis Example 1C, as component (C). After adding 0.025 g of 2-ethyl-4-methylimidazole (2E4 MZ, trade name of Shikoku Chemicals Corp.) as a curing accelerator, the mixture was combined with 46 g of N-methyl-2-pyrrolidone and 15 g of methyl ethyl ketone to prepare an adhesive layer resin varnish for Preparation Example 4C (solid concentration: approximately 20 wt %).

The resin composition obtained by curing the resin comprising 2E4 MZ added to DER-331L and KA-1163 had a glass transition temperature (Tg) of 135° C.

### Comparative Preparation Example 1C

To 50 g of the polyamideimide NMP solution obtained in Synthesis Example 1C there was added 50 g of N-methyl-2-pyrrolidone, to prepare an adhesive resin varnish (solid concentration: approximately 15 wt %) for Comparative Preparation Example 1C.

### Comparative Preparation Example 2C

To 50 g of the polyamideimide NMP solution obtained in Synthesis Example 2C there was added 8.8 g of a cresol-novolac-type epoxy resin (YDCN-500, trade name of Tohto Kasei Co., Ltd.). After adding 0.088 g of 2-ethyl-4-methylimidazole (2E4 MZ, trade name of Shikoku Chemicals Corp.) as a curing accelerator, the mixture was combined with 101 g of N-methyl-2-pyrrolidone and 34 g of methyl ethyl ketone to prepare an adhesive layer resin varnish for Comparative Preparation Example 2 (solid concentration: approximately 15 wt %).

### [Fabrication of Insulating Resin Layer (Insulating Layer) Prepregs]

Insulating resin layer prepregs for Fabrication Examples 1 and 3 were produced by the same method as described above. An insulating resin layer prepreg for Fabrication Example 4 was also produced by the following method.

### Fabrication Example 4

First, 333 g of toluene and 26.5 g of a polyphenylene ether resin (ZILON S202A, trade name of Asahi Kasei Chemicals Corp.) were placed in a 2 L separable flask equipped with a condenser tube, thermometer and stirrer, and the mixture was stirred to dissolution while heating the flask to 90° C. Next, 100 g of 1,2-polybutadiene (B-3000, trade name of Nippon Soda Co., Ltd.) and 15.9 g of N-phenylmaleimide as a crosslinking aid were added to the flask while stirring, and upon confirming dissolution or uniform dispersion, the mixture was cooled to room temperature. After then adding 3.0 g of α,α′-bis(t-butylperoxy)diisopropylbenzene (PERBUTYL P, trade name of NOF Corp.) as a radical polymerization initiator, 70 g of toluene was further added to obtain an insulating resin layer varnish with a solid concentration of approximately 30 wt %.

The obtained insulating resin layer varnish was impregnated into 0.1 mm-thick glass fibers (E glass, product of Nitto Boseki Co., Ltd.), and then heated and dried at 120° C. for 5 minutes to obtain an insulating resin layer prepreg for Fabrication Example 4, having a resin content of 50 wt %.

### Examples 1C-4C, Comparative Examples 1C-4C

### Fabrication of Adhesive Layer-Attached Conductive Foils

Each of the adhesive layer resin varnishes obtained in Preparation Examples 1C-4C and Comparative Preparation Examples 1C-2C was coated by natural casting onto the M-surface [surface roughness (Rz)=0.8 μm) of a 12 μm-thick electrolytic copper foil (F0-WS-12, low-profile copper foil by Furukawa Circuit Foil Co., Ltd.), and then dried at 150° C. for 5 minutes to fabricate adhesive layer-attached conductive foils for Examples 1C-4C and Comparative Examples 1C-2C. All of the thicknesses of the dried adhesive layers before curing were 3 μm. Use of the adhesive layer resin varnishes of Preparation Examples 1C, 2C, 3C and 4C corresponds to Examples 1C, 2C, 3C and 4C, and use of the adhesive layer resin varnishes of Comparative Preparation Examples 1C and 2C corresponds to Comparative Examples 1C and 2C.

### (Fabrication of Double-Sided Copper Clad Laminates)

Each of the aforementioned adhesive layer-attached conductive foils was adhered onto both main sides of a base comprising four laminated insulating resin layer prepregs of one of Fabrication Examples 1, 3 and 4, with their adhesive layers in contact therewith, to obtain laminated bodies. Each of the laminated bodies was then molded by hot pressing in the lamination direction under pressing conditions of 200° C., 3.0 MPa, 70 minutes, to fabricate double-sided copper clad laminates (0.55 mm thickness) for Examples 1C, 2C, 3C and 4C and for Comparative Examples 1C and 2C. The combinations of the adhesive layer resin varnishes and insulating resin layer prepregs of each of the examples and comparative examples were as shown in Table 3 below.

Also, an 18 μm-thick electrolytic copper foil A (F0-WS-12, trade name of Furukawa Electric Co., Ltd., Rz=0.8 μm) without adhesive layers or an 18 μm-thick electrolytic copper foil B (GTS-12, trade name of ordinary copper foil by Furukawa Electric Co., Ltd., M-surface Rz=8 μm) without adhesive layers was adhered to both main sides of a base comprising four laminated insulating resin layer prepregs of Fabrication Example 1, with the M-surfaces in contact with the main side of the base, to obtain a laminated body. Each of the laminated bodies was then molded by hot pressing in the lamination direction under pressing conditions of 200° C., 3.0 MPa, 70 minutes, to fabricate double-sided copper clad laminates (0.55 mm thickness) for Comparative Examples 3C and 4C. The laminated body comprising electrolytic copper foil A was used as the double-sided copper clad laminate (0.55 mm thickness) for Comparative Example 3C, and the one comprising electrolytic copper foil B was used for Comparative Example 4C.

(Fabrication of Multilayer Boards)

First, double-sided copper clad laminates for Examples 1C-4C and Comparative Examples 1C-4C were formed in the same manner as above, and the copper foil sections were completely removed by etching. Next, the same prepregs as the insulating resin layer prepregs used for fabrication of the copper clad laminates were situated on either side of each of the copper foil-removed double-sided copper clad laminates, and 12 μm-thick electrolytic copper foils [GTS-12, trade name of ordinary copper foil by Furukawa Electric Co., Ltd., M-surface Rz=8 μm] without adhesive layers were adhered to the outside thereof with the M-surfaces in contact therewith, and hot pressure molding was performed in the lamination direction under pressing conditions of 200° C., 3.0 MPa, 70 minutes to fabricate multilayer boards corresponding to Examples 1C-4C and Comparative Examples 1C-4C.

### [Evaluation of Physical Properties]

(Measurement of Copper Foil Peel Strengths of Double-Sided Copper Clad Laminates)

The double-sided copper clad laminates obtained in Examples 1C-4C and Comparative Examples 1C-4C were used to measure the copper foil peel strengths (units: kN/m) by the same method described above. The results are shown in Table 3.

The copper foil peel strength indicated as “−” in the table means that the copper foil peel strength could not be measured because the copper foil had already peeled after being held in the PCT.

(Evaluation of Soldering Heat Resistance of Double-Sided Copper Clad Laminates and Multilayer Boards)

The double-sided copper clad laminates and multilayer boards obtained in Examples 1C-4C and Comparative Examples 1C-4C were used for evaluation of their soldering heat resistance by the same method as described above. The results are shown in Table 3.

(Evaluation of Transmission Loss of Double-Sided Copper Clad Laminates)

The transmission loss (units: dB/m) of each of the double-sided copper clad laminates obtained in Examples 1C-4C and Comparative Examples 1C-4C was measured in the same manner as described above. The results are shown in Table 3.

TABLE 3

| | | | Example | Example | Example | Example | Comp. | Comp. | Comp. | Comp. |
|---|---|---|---|---|---|---|---|---|---|---|
| | | | 1C | 2C | 3C | 4C | Ex. 1C | Ex. 2C | Ex. 3C | Ex. 4C |
| Adhesive layer resin varnish | | | Preparation | Preparation | Preparation | Preparation | Comp. | Comp. | — | — |
| | | | Ex. | Ex. | Ex. | Ex. | Preparation | Preparation | | |
| | | | 1C | 2C | 3C | 4C | Ex. | Ex. | | |
| | | | | | | | 1C | 2C | | |
| Insulating resin layer | | | Fabrication | Fabrication | Fabrication | Fabrication | Fabrication | Fabrication | Fabrication | Fabrication |
| prepreg | | | Ex. 1 | Ex. 4 | Ex. 3 | Ex. 3 | Ex. 1 | Ex. 4 | Ex. 1 | Ex. 4 |
| Peel strength | | Original | 0.82 | 1.08 | 0.95 | 0.88 | 1.32 | 1.21 | 0.20 | 0.90 |
| (kN/m) | | state | | | | | | | | |
| | | After PCT | 0.71 | 0.82 | 0.74 | 0.66 | 0.80 | 0.71 | — | 0.33 |
| Soldering | Copper- | Original | 3 | 3 | 3 | 3 | 3 | 3 | 2 | 3 |
| heat | clad | state | | | | | | | | |
| resistance | board | 1 hr | 3 | 3 | 3 | 3 | 3 | 3 | 0 | 3 |
| (original | | 2 hrs | 3 | 3 | 3 | 3 | 3 | 3 | 0 | 3 |
| state/after | | 3 hrs | 3 | 3 | 3 | 3 | 3 | 3 | 0 | 3 |
| PCT) | | 4 hrs | 3 | 3 | 3 | 2 | 2 | 3 | 0 | 3 |
| | | 5 hrs | 3 | 3 | 3 | 0 | 0 | 2 | 0 | 3 |
| | Multilayer | Original | 3 | 3 | 3 | 3 | 3 | 3 | 2 | 3 |
| | board | state | | | | | | | | |
| | | 1 hr | 3 | 3 | 3 | 3 | 1 | 3 | 0 | 3 |
| | | 2 hrs | 3 | 3 | 3 | 3 | 0 | 1 | 0 | 3 |
| | | 3 hrs | 3 | 3 | 3 | 2 | 0 | 0 | 0 | 3 |
| | | 4 hrs | 3 | 3 | 3 | 1 | 0 | 0 | 0 | 3 |
| | | 5 hrs | 3 | 3 | 2 | 0 | 0 | 0 | 0 | 3 |

| | | | | | | | | |
|---|---|---|---|---|---|---|---|---|
| Transmission loss (dB/m) | 4.60 | 4.18 | 4.75 | 4.70 | 4.63 | 4.25 | 4.56 | 5.68 |

The results for the examples and comparative examples shown above confirmed that the present invention can provide adhesive layer-attached conductive foils and conductor-clad laminated sheets that exhibit sufficient reduction in transmission loss in the high-frequency band, and that can form printed circuit boards with adequately increased adhesive force between insulating layers and conductive layers. Therefore, printed circuit boards and multilayer interconnection boards obtained using them have low transmission loss and satisfactory heat resistance (especially satisfactory heat resistance after moisture absorption).

1. An adhesive layer-attached conductive foil provided with a conductive foil and an adhesive layer formed on the conductive foil, wherein
the adhesive layer is composed of a curable resin composition containing
component (A): a polyfunctional epoxy resin,
component (B): a polyfunctional phenol resin and
component (C): a polyamideimide.

2. An adhesive layer-attached conductive foil according to claim 1, wherein component (C) is a polyamideimide with a weight-average molecular weight of between 50,000 and 300,000.

3. An adhesive layer-attached conductive foil according to claim 1, wherein component (A) and component (B) are such that their mixture has a post-curing glass transition temperature of above 150° C.

4. An adhesive layer-attached conductive foil according to claim 1, wherein component (A) contains at least one type of epoxy resin selected from the group consisting of phenol-novolac-type epoxy resins, cresol-novolac-type epoxy resins, brominated phenol-novolac-type epoxy resins, bisphenol A-novolac-type epoxy resins, biphenyl-type epoxy resins, naphthalene backbone-containing epoxy resins, aralkylene backbone-containing epoxy resins, biphenyl-aralkylene backbone-containing epoxy resins, phenolsalicylaldehyde-novolac-type epoxy resins, lower alkyl group-substituted phenolsalicylaldehyde-novolac-type epoxy resins, dicyclopentadiene backbone-containing epoxy resins, polyfunctional glycidylamine-type epoxy resins and polyfunctional alicyclic epoxy resins.

5. An adhesive layer-attached conductive foil according to claim 1, wherein component (B) contains at least one type of polyfunctional phenol resin selected from the group consisting of aralkyl-type phenol resins, dicyclopentadiene-type phenol resins, salicylaldehyde-type phenol resins, copolymer resins of benzaldehyde-type phenol resins and aralkyl-type phenol resin, and novolac-type phenol resins.

6. An adhesive layer-attached conductive foil according to claim 1, wherein component (C) contains a structural unit comprising a saturated hydrocarbon.

7. An adhesive layer-attached conductive foil according to claim 1, wherein the mixing proportion of component (C) is 0.5-500 parts by weight with respect to 100 parts by weight as the total of component (A) and component (B).

8. An adhesive layer-attached conductive foil according to claim 1, wherein the curable resin composition further contains crosslinked rubber particles and/or a polyvinylacetal resin as component (D).

9. An adhesive layer-attached conductive foil according to claim 8, wherein component (D) is at least one type of crosslinked rubber particles selected from the group consisting of acrylonitrile-butadiene rubber particles, carboxylic acid-modified acrylonitrile-butadiene rubber particles and butadiene rubber-acrylic resin core-shell particles.

10. An adhesive layer-attached conductive foil according to claim 1, wherein the adhesive layer is obtained by coating the surface of the conductive foil with a resin varnish containing the curable resin composition and a solvent to form a resin varnish layer, and then removing the solvent from the resin varnish layer.

11. An adhesive layer-attached conductive foil according to claim 1, wherein the adhesive layer has a thickness of 0.1-10 μm.

12. An adhesive layer-attached conductive foil according to claim 1, wherein the ten-point height of irregularities (Rz) on the side of the conductive foil on which the adhesive layer is formed is no greater than 4 μm.

13. A conductor-clad laminated sheet obtained by laminating an adhesive layer-attached conductive foil according to claim 1 onto at least one side of an insulating resin film containing a resin with an insulating property, so that the adhesive layer of the adhesive layer-attached conductive foil contacts therewith, to obtain a laminated body, and then heating and pressing the laminated body.

14. A conductor-clad laminated sheet comprising an insulating layer and a conductive layer laminated on the insulating layer via an adhesive cured layer, wherein
the adhesive cured layer and conductive layer are formed from an adhesive layer-attached conductive foil according to claim 1, and
the adhesive cured layer consists of the cured adhesive layer of the adhesive layer-attached conductive foil and the conductive layer consists of the conductive foil of the adhesive layer-attached conductive foil.

15. A conductor-clad laminated sheet comprising an insulating layer, a conductive layer situated facing the insulating layer and an adhesive cured layer sandwiched between the insulating layer and conductive layer, wherein
the adhesive cured layer consists of a cured resin composition comprising
component (A): a polyfunctional epoxy resin
component (B): a polyfunctional phenol resin and
component (C): a polyamide resin.

16. A conductor-clad laminated sheet according to claim 15, wherein the insulating layer is constructed using an insulating resin and a base material situated in the insulating resin, and
the base material comprises a woven fabric or nonwoven fabric of fibers composed of one or more materials selected from the group consisting of glass, paper and organic polymers.

17. A conductor-clad laminated sheet according to claim 16, wherein the insulating layer contains a resin with an ethylenic unsaturated bond as the insulating resin.

18. A conductor-clad laminated sheet according to claim 16, wherein the insulating resin contains at least one type of resin selected from the group consisting of polybutadiene, polytriallyl cyanurate, polytriallyl isocyanurate, unsaturated group-containing polyphenylene ethers and maleimide compounds.

19. A conductor-clad laminated sheet according to claim 16, wherein the insulating resin contains at least one type of resin selected from the group consisting of polyphenylene ethers and thermoplastic elastomers.

20. A conductor-clad laminated sheet according to claim 15, wherein the insulating layer has a relative permittivity of no greater than 4.0 at 1 GHz.

21. A printed circuit board obtained by working the conductive layer of a conductor-clad laminated sheet according to claim 15 into a prescribed circuit pattern.

22. A multilayer interconnection board comprising a core board having at least one printed circuit board layer, and an outer circuit board having at least one printed circuit board layer and situated on at least one side of the core board,
wherein at least one printed circuit board layer of the core board is a printed circuit board according to claim 21.
